(19) United States
(12) Patent Application Publication
(10) Pub. No.: US 2025/0171091 A1
(43) Pub. Date: May 29, 2025

(54) MAGNETIC FIELD SYSTEMS AND METHODS

(71) Applicant: Zero Nox, Inc., Porterville, CA (US)

(72) Inventor: James Matthew KERTON, Duncan (CA)

(21) Appl. No.: 18/722,418

(22) PCT Filed: Dec. 20, 2022
(86) PCT No.: PCT/US2022/082076

§ 371 Date: Jun. 20, 2024

Related U.S. Application Data
(60) Provisional application No. 63/265,818, filed on Dec. 21, 2021.
(60) Provisional application No. 63/265,819, filed on Dec. 21, 2021.

(51) Int. Cl. B62D 35/00; H02S 10/20; H02S 20/30; H02S 40/22

(52) U.S. Cl. CPC B62D 35/00; H02S 10/20; H02S 20/30; H02S 40/22

(57) ABSTRACT

A solar energy conversion system configured to increase a flux of photons from solar radiation can include a solar panel comprising a semiconductor substrate, a permanent magnet having a helical shape, an electromagnetic receiver, an antenna disposed along at least a portion of the permanent magnet, and an inverse spin hall effect (ISHE) generator configured to modify a velocity of photons moving toward the base of the permanent magnet. The ISHE generator can include a positive electrical coupling, a negative electrical coupling, a polymer layer disposed axially above and between the positive and negative electrical couplings, a ferromagnet, and a plurality of electrical couplings. In response to a magnetic field produced by the permanent magnet, the positive and negative electrical couplings can generate a flow of electrons in response to a spin current within the polymer layer.

### INCORPORATION BY REFERENCE

This application claims priority to U.S. Provisional Application No. 63/265,818, filed Dec. 21, 2021, entitled “ELECTROMAGNETIC FIELD AERODYNAMICS SYSTEM,” U.S. Provisional Application No. 63/265,819, filed Dec. 21, 2021, entitled “PHOTOVOLTAIC VORTEX MAGNETIC FIELD PHOTON AMPLIFIER SYSTEM,” each of which is hereby incorporated by reference in its entirety herein and made part of this disclosure. Any and all applications for which a foreign or domestic priority claim is identified in the Application Data Sheet as filed with the present application are hereby incorporated by reference under 37 CFR 1.57

### FIELD

This disclosure relates to photovoltaic systems and aerodynamic systems, related devices, and applications thereof.

### BACKGROUND

The demand for improved methods for converting light energy into electrical energy and for improving the aerodynamics of moving objects has increased dramatically over the past century. Accordingly, a way to better use, generate, or conserve cleaner energy is needed.

### SUMMARY

Neither the preceding summary nor the following detailed description purports to limit or define the scope of protection. The scope of protection is defined by the claims.

As the demand for energy increases, the demand to harvest energy from untapped or under-exploited sources has increased as well, especially those sources readily available like sunlight. Accordingly, various devices and systems are disclosed herein that address one or more of these problems. For example, devices and systems are disclosed herein that incorporate an improved photovoltaic cell and/or acrodynamic system for converting light energy into electrical energy and for reducing fluid drag on a moving object.

A solar energy conversion system can be configured to increase a flux of photons from solar radiation. The system may include a solar panel, a permanent magnet, an electromagnetic receiver, an antenna, and an inverse spin hall effect (ISHE) generator.

The solar panel can include a semiconductor substrate extending generally along a plane and configured to convert the flux of photons from solar radiation to electrical power. The solar panel can include a frame extending about a periphery of the semiconductor substrate.

The permanent magnet can include a body having a helical shape extending along an axis perpendicular to the plane. The body can include a base and a free end. The base connected to the solar panel. The helical shape can have a decreasing diameter along the axis toward the free end. The helical shape of the body can have a largest diameter proximate the base relative to a diameter of the body proximate the free end. The body can have a decreasing thickness along the axis toward the free end. The body can have a greatest thickness proximate the base relative to a thickness of the body proximate the free end. A magnitude of a magnetic field of the permanent magnet may be greatest proximate the base relative to a magnitude of the magnetic field of the permanent magnet proximate the free end. The magnetic field attracts photons toward the base of the permanent magnet.

The electromagnetic receiver may be configured to generate electromagnetic waves configured to resonate with the magnetic field of the permanent magnet to direct photons toward the permanent magnet to increase the flux of photons that are attracted toward the base of the permanent magnet. The antenna may be disposed along at least a portion of the permanent magnet. The antenna configured to emit the electromagnetic waves generated by the electromagnetic receiver.

The ISHE generator can be configured to modify a velocity of photons moving toward the base of the permanent magnet to direct the increased flux of photons toward the semiconductor substrate. The ISHE may be connected to and extending along the frame of the solar panel. The ISHE generator can include a positive electrical coupling, a negative electrical coupling, and a polymer layer disposed axially above and between the positive and negative electrical couplings. The polymer layer can include a dielectric. The ISHE generator can further include a ferromagnet that is coupled axially above the polymer layer and configured to generate a second magnetic field. The polymer layer can separate the positive and negative couplings from each other and separates the ferromagnet from each of the positive and negative couplings. The dielectric can be configured to increase resistance of a flow of electricity between the ferromagnet and the positive or negative electrical couplings via the polymer layer. In response to the second magnetic field applied to the polymer layer, the ferromagnet can be configured to modify a velocity of photons to increase absorption of the photons by the semiconductor substrate.

The ISHE generator may further include a plurality of electrical leads each coupled to corresponding of the positive and negative electrical couplings. Each of the plurality of electrical leads may be disposed substantially parallel to the plane and to an edge of the semiconductor substrate. Each of the electrical leads may be configured to transmit electrical current orthogonal to the second magnetic field produced by the ferromagnet. In response to the second magnetic field. the positive and negative electrical couplings may be configured to generate a flow of electrons along the plurality of electrical leads in response to a spin current of electrons within the polymer layer.

A vehicle aerodynamic system configured to reduce fluid drag on a vehicle can include a plurality of piezoceramic transducers, a plurality of pressure sensors, a controller, an ISHE generator, an antenna, an electromagnetic receiver, and a plurality of dielectric rods.

The plurality of piezoceramic transducers configured to be positioned proximate to an exterior surface of the vehicle. The plurality of piezoceramic transducers may each be configured convert electric current from a battery of the vehicle to ultrasound waves and to emit the ultrasound waves toward ambient airflow proximate the exterior surface of the vehicle that exerts pressure on the exterior of the vehicle as the vehicle moves through ambient air to convert turbulent flow of the ambient airflow to laminar flow proximate the exterior of the vehicle. This may help reduce pressure exerted by the ambient airflow on the exterior of the vehicle moving through ambient air, thereby reducing airflow drag on the vehicle.

The plurality of pressure sensors may be configured to be positioned proximate to the exterior surface of the vehicle. The plurality of pressure sensors may each be configured to detect a pressure of the ambient airflow at a location of a corresponding piezoceramic transducer and to generate a pressure signal corresponding to the pressure at the location.

The controller may be configured to receive the pressure signal from each of the plurality of pressure sensors and to determine a target ultrasound wave based on the pressure signal and to cause the corresponding piezoceramic transducer to emit the target ultrasound wave to convert turbulent flow of the ambient airflow to laminar flow of the ambient airflow proximate the exterior of the vehicle to reduce airflow drag on the vehicle.

The ISHE generator may be configured to be positioned at least partially about an electric motor or at least partially about a shell or a chassis of the vehicle. The ISHE generator can be configured to generate electric power from an electromagnetic field generated by the electric motor of the vehicle. The ISHE generator may include a positive electrical coupling, a negative electrical coupling, and a ferromagnet configured to generate a second electromagnetic field to modify the electromagnetic field generated by the electric motor.

The ISHE generator may further include a polymer layer disposed on and between each of the positive and negative electrical couplings. The polymer layer can separate the positive and negative couplings from each other and separates the ferromagnet from each of the positive and negative couplings. The polymer layer may include a dielectric that increases resistance of a flow of electricity between the ferromagnet and the positive or negative electrical couplings via the polymer layer.

The ISHE generator may further include a plurality of electrical leads each coupled to corresponding of the positive and negative electrical couplings. Each of the plurality of electrical leads may be disposed about the electric motor of the vehicle. Each of the electrical leads can be configured to interact with the polymer layer and with the electromagnetic field generated by the electric motor and modified by the ferromagnet. In response to an interaction of the plurality of electrical leads with the polymer layer and with the modified electromagnetic field, the positive and negative electrical couplings are configured to generate a flow of electrons along the plurality of electrical leads in response to a spin state of electrons within the polymer layer to at least one of power the plurality of piezoceramic transducers or charge the battery of the vehicle via the flow of electrons.

The antenna may be configured to be positioned at least partially about the electric motor of the vehicle. The antenna can be configured to detect an electromagnetic field emitted by the electric motor and to generate a field signal indicative of the electromagnetic field.

The electromagnetic receiver can be configured to receive the field signal from the antenna and to determine, based on the field signal, resonance electromagnetic waves that resonate with the electromagnetic field emitted by the electric motor. The electromagnetic receiver can be configured to cause the antenna to emit the resonance electromagnetic waves toward the shell or the chassis of the vehicle. The electromagnetic field emitted by the electric motor corresponds to a speed of operation of the electric motor.

The plurality of dielectric rods may each be configured to connect to the shell or the chassis of the vehicle and to the electric motor. Each of the plurality of dielectric rods can be configured to receive the electromagnetic field from the electric motor and to transmit the electromagnetic field to the shell or the chassis of the vehicle.

### BRIEF DESCRIPTION OF THE DRAWINGS

The abovementioned and other features of the embodiments disclosed herein are described below with reference to the drawings of the embodiments. The illustrated embodiments are intended to illustrate, but not to limit, the scope of protection. Various features of the different disclosed embodiments can be combined to form further embodiments, which are part of this disclosure. In the drawings, similar elements may have reference numerals with the same last two digits.

FIG. 1A shows a top view of the solar energy conversion system, according to one embodiment.

FIG. 1B shows a side view of the solar energy conversion system of FIG. 1A.

FIG. 1C shows how the magnetic field of the permanent magnet can draw in additional photons, thereby increasing a flux of the photons.

FIG. 1D shows how in some embodiments the virtual photons may form a cloud that generally surrounds the permanent magnet.

FIG. 2A shows a top view of an example inverse spin hall effect (ISHE) generator, according to one embodiment.

FIG. 2B shows a side view of the portion of the ISHE generator of FIG. 2A.

FIG. 3 shows an example implementation of the ISHE generator for creating spin current.

FIG. 4 shows another example of a solar energy conversion system that does not include an antenna, an ISHE generator, or an electromagnetic receiver.

FIG. 5 shows an example method that may be performed by an example solar energy conversion system described herein.

FIG. 6A shows an example fluid dynamic system that is configured to reduce fluid drag on a moving object, such as a vehicle (e.g., car, plane, boat, rocket, etc.), according to one embodiment.

FIG. 6B shows another example fluid dynamic system that does not include an electromagnetic receiver, any rods, or an antenna, according to one embodiment.

FIG. 6C shows another fluid dynamic system that does not include a ISHE generator (including electrical leads), according to one embodiment

FIG. 6D shows an example fluid dynamic system that includes a plurality of ISHE generators and a motor casing antenna disposed at least partially between the ISHE generators on or about the motor casing.

FIG. 7 shows an example of a fluid dynamic system that includes a plurality of transducers and a controller.

FIG. 8 shows an example inverse hall effect (IHE) generator, according to one embodiment.

FIG. 9 shows an example method that may be performed by an example fluid dynamic system described herein.

FIG. 10 shows another example method that may be performed by an example fluid dynamic system described herein.

### DETAILED DESCRIPTION

Although certain embodiments and examples are described below, this disclosure extends beyond the specifically disclosed embodiments and/or uses and obvious modifications and equivalents thereof. Thus, it is intended that the scope of this disclosure should not be limited by any particular embodiments described below. Furthermore, this disclosure describes many embodiments in reference to power generation or phase shifting but any embodiment and modifications or equivalents thereof should not be limited to the foregoing.

A magnetic field is a vector field that describes the magnetic influence on moving electric charges, electric currents and magnetic materials. A moving charge in a magnetic field experiences a force perpendicular to its own velocity and to the magnetic field. Magnetic resonance comprises of the absorption or emission of electromagnetic radiation by electrons or atomic nuclei in response to the application of certain magnetic fields. Electromagnetic radiation comprises the flow of energy at the universal speed of light through free space or through a material medium in the form of the electric and magnetic fields that make up electromagnetic waves such as radio waves, visible light, and gamma rays. Electromagnetic radiation is produced whenever a charged particle, such as an electron, changes its velocity (e.g., whenever it is accelerated or decelerated). If a charged particle interacts with an electromagnetic wave, it experiences a force proportional to the strength of the electric field and thus is forced to change its motion in accordance with the frequency of the electric field wave. In doing so, it becomes a source of electromagnetic radiation of the same frequency

As disclosed herein, electrons can be manipulated by influencing magnetic fields. Described herein are systems and devices for manipulating electrons for various purposes. For example, electromagnetic resonance can be used to reduce or lower the effects of aerodynamic drag on a surface. In other examples, changes in magnetic fields can be used to manipulate electrons in order to provide a corollary for photons.

Electromagnetic energy is not currently being harnessed or conserved as effectively as could be done. For example, modern photovoltaic cells generally prioritize the energy that is available at a surface of a solar panel. This approach omits the three dimensions available to energy capture. A natural flux of photons that comes from a light source (e.g., the sun) can be increased using features described herein. This allows for an increase flux of photons and thus an increased conversion of light into energy.

As another example, electromagnetic energy can be better conserved and stored for moving objects, such as vehicles, that use electrical motors. The electrical motors emit an electromagnetic field (e.g., a magnetic field) that contains energy that can be harnessed and stored. Features described herein can capture that energy.

Moreover, other features described herein can reduce a loss of energy due to movement of an object. For example, fluid resistance can slow down a moving object due in part to higher pressures exerted on an outer surface or frame of the object. The higher pressures may be caused in part from turbulent flow of the fluid. Laminar flow, by contrast, of the fluid can allow the object to move through the fluid with lower pressure and thus with lower energy loss.

### Light Energy Conversion Systems

Using magnetic fields to control electrons is a founding principle of electronics, but a corollary for photons had not previously existed. When an electron approaches a magnetic field, it meets resistance and opts to follow the path of least effort, traveling in a circular motion around the field. Following these known principles, a synthetic magnetic field rotating in a vortex formation can be used to collect a more dense volume of photon packets, increasing density with every vortex cycle to the singular point.

A rotating “vortex beam” whose twist changes across the length of the beam has been created in the lab for the first time. A beam of light can have orbital angular momentum, meaning that the beam twists as it propagates forward, with each photon circling around the center of the beam. With momentum densities of even massless energy can be increased or decreased.

With momentum, a suctioning effect can be used to attract, draw in, focus, and even trap light. A demonstration of this in nature, with regards to black hole phenomenon, can be seen. By rotating the synthetic magnetic field in a vortex formation the energy density collected at a unique designed photovoltaic panel can be amplified as a singular point of contact with the synthetic magnetic field vortex. Due to the unique non intersecting points of action known in non-Euclidean geometry and vortex dynamics, fragile photon packets may not interact, but only increase in volume as time per revolutions increases and decreases. This can increase or decrease a frequency and/or strength until point of singular contact of the photovoltaic receiver. Photon packets upon interaction with themselves prior to singular point photovoltaic interaction may release their energy prematurely and be wasted. The reaction dynamically will be a magnetic field vacuum tuned to draw in desirable energy reducing or minimizing a footprint and enabling scalability to smaller applications, maintaining a high energy density based on the synthetic magnetic field strength.

Embodiments described herein utilize a self-excited electro-magnetic apparatus, seen in similar self-excited generator systems driven by frequency flux on a fixed parameter to initiate a synthetic magnetic vortex rotational field. The photovoltaic receiver can include a cone shape as to distribute the photon packets over a more suitable surface area to minimize energy loss to photon packet interaction at the singular point of the vortex prior to desired photovoltaic engagement. This may improve output exponentially. By using a fixed parameter electromagnetic system moving parts can be eliminated by expanding on known electromagnetic resonance phenomenon and a matched resonance field generator.

Embodiments described herein modernize a utilization of solar radiation as a renewable source of energy. For example, some embodiments offer a full 3-dimensional interaction with environment, helping attainable higher levels of efficiency, such as up to 5, 10, 20 or more percent increase in efficiency in comparison to existing systems. This system is a fixed solar radiation interaction system and designed to enhance current technology in use currently. Embodiments can be configured to optimize solar radiation renewable energy allocation.

Embodiments described herein employ 3-dimensional physics of the current 2-dimensional systems in operation today. Electromagnetic resonance is a phenomenon produced by simultaneously applying steady magnetic field and electromagnetic radiation (e.g., radio waves) to a sample of electrons and then adjusting both the strength of the magnetic field and the frequency of the radiation to produce absorption of the radiation. The resonance refers to the enhancement of the absorption that occurs when the correct combination of field and frequency is obtained.

The bulk spin photovoltaic (BSPV) effect for creating DC spin current under light illumination. BSPV can break inversion symmetry. BSPV may apply to a broad range of materials and may be readily integrated with existing semiconductor technologies. The BSPV effect is related to the bulk photovoltaic (BPV) effect. In BPV, a DC charge current is generated under light. Using the different selection rules on spin and charge currents, a pure spin current may be realized if the system possesses mirror symmetry or inversion-mirror symmetry.

An Inverse Spin Hall Effect can be used to amplify the photon input to a photovoltaic system. The Inverse Spin Hall Effect can be arranged to encase the solar photovoltaic panel and amplify the input. Permanent magnets can be utilized in a curl shape rising above the photovoltaic panel. The height may be equal to the diameter of the panel. The magnets can vary in thickness, a gradual increase in thickness from the top to the bottom. This arrangement can give provide a magnetic behavior that increases in strength closer to the photovoltaic pad. A small RF or microwave antenna and manual tuning receiver can be applied to the magnetic field generator installed to the panel, which can increase the photovoltaic energy output capability.

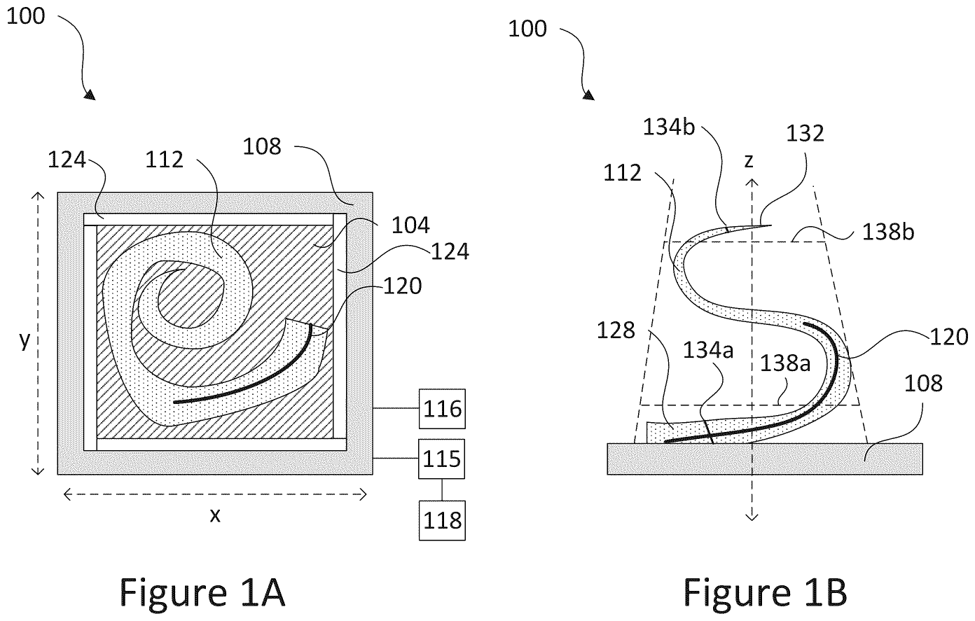

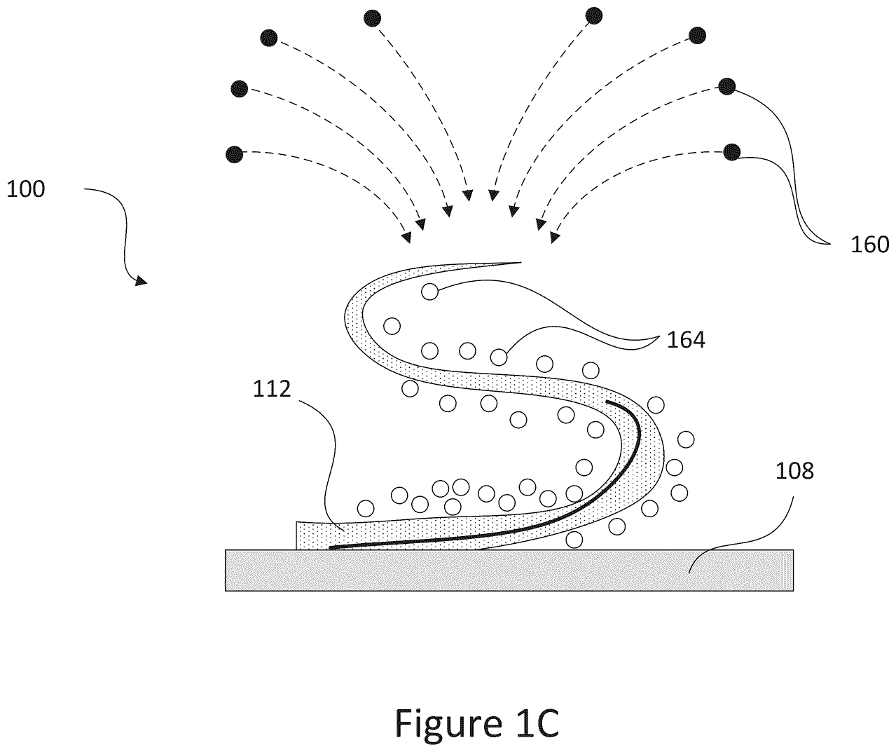

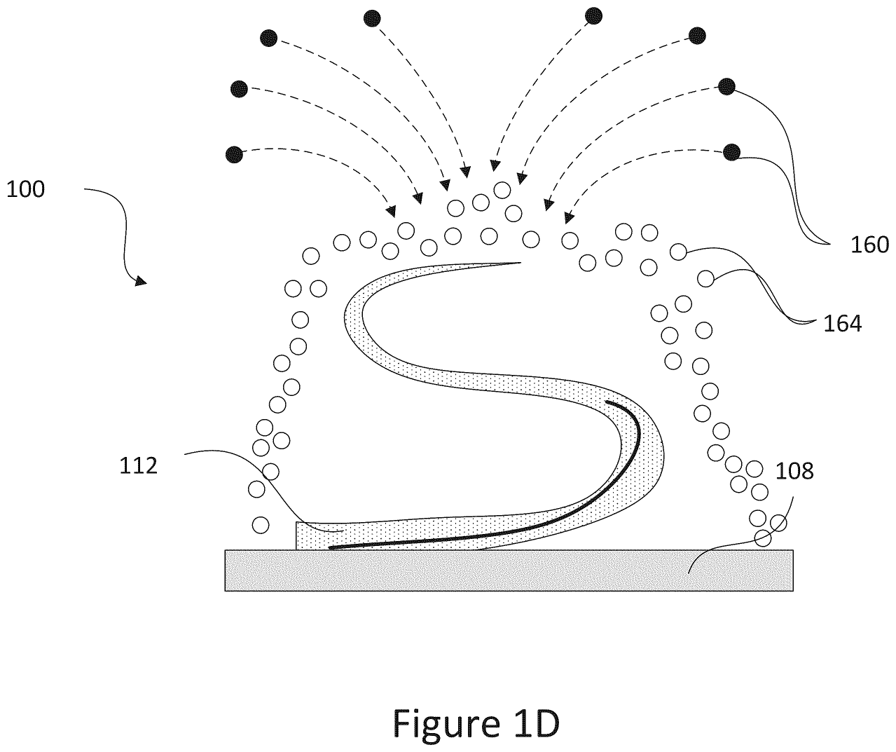

FIGS. 1A-1B show an example solar energy conversion system 100, according to one embodiment. Although the solar energy conversion system 100 references solar energy, any optical energy from any source (e.g., not just the sun) is contemplated, such as artificial light. FIG. 1A shows a top view of the solar energy conversion system 100 and FIG. 1B shows a side view of the solar energy conversion system 100. The solar energy conversion system 100 can include a solar panel 104 that is surrounded by a frame 108. The solar panel 104 can comprise one or more solar modules. The solar panel 104 may be generally rectangular (e.g., square) as shown, although other shapes are possible, such as a circle, triangle, or some combination of those shapes. A ratio of a width of the semiconductor substrate to a maximum height along the z-axis of the permanent magnet 112 may be greater than 1, greater than 2, greater than 3, or greater than 4. A length of the solar panel 104 may be between about 0.5 cm to about 10 cm in some embodiments. In some embodiments, the length may be about 1 cm to about 2 cm. The width may be equal to the length in some embodiments. In some embodiments, solar energy conversion system 100 may include a 3×3, 5×5, 25×25, or 100×100 grid of solar panels 104. Other arrangements are possible.

The solar panel 104 can convert energy from a light source (e.g., the sun, artificial lights) into a flow of electrons by the photovoltaic effect. The solar energy conversion system 100 can produce direct current electricity from the light source. The energy may be used to power equipment, such as those described herein, and/or to recharge batteries. The solar panel 104 may produce direct current (DC). In some embodiments, the solar energy conversion system 100 can include an inverter (not shown) to convert the DC to alternating current (AC) if needed.

The solar panel 104 can include a semiconductor substrate, which may utilize the photovoltaic effect. The solar panel 104 can be connected with other such solar panels (e.g., via electrical wires) to form modules, arrays, and/or other arrangements. The semiconductor substrate may extend generally along a plane. As shown in FIG. 1A, for convenience, the plane may extend in along the x-y plane. Using the photovoltaic effect, the semiconductor substrate can convert a flux of photons from solar radiation to electrical power. The area of the flux may be defined generally parallel to the x-y plane. For example, the area may be approximately equal to an area of the amount of exposed semiconductor substrate, although the area may be dependent on an angle of incidence of the light source. The frame 108 can extend about a periphery of the semiconductor substrate.

To improve the energy conversion, the solar energy conversion system 100 may include one or more permanent magnets 112 that are connected (e.g., electrically connected) to the solar panel 104. For simplicity, reference to one permanent magnet 112 will be made herein. The permanent magnet 112 can include a body having a helical or screw shape. The body of the permanent magnet 112 may extend along an axis perpendicular to the x-y plane. As shown in FIG. 1B, the axis may generally extend along the z-axis shown. Although reference herein is to a permanent magnet, the permanent magnet 112 may additionally or alternatively include an electromagnetic that otherwise has the features described herein.

The body of the permanent magnet 112 can include a base 128 and a free end 132. The base 128 can be connected to the solar panel. For example, the base 128 may be directly connected to a surface of the solar panel 104 in some embodiments. Additionally or alternatively, the base 128 may be connected to the frame 108. The frame 108 may be somewhat thicker (e.g., along the z-axis) than the solar panel 104, in some embodiments.

The helical shape can have a decreasing diameter along the axis toward the free end 132. For example, the diameter may gradually decrease along the z-axis such that a diameter 138a of the permanent magnet 112 is smaller than a diameter 138b near the free end 132. Additionally or alternatively, the helical shape of the body can have a largest diameter proximate the base 128 relative to a diameter of the base 128 proximate the free end. The diameter of the helix may be measured generally transverse (e.g., orthogonal) to the z-axis in some embodiments.

The body can have a decreasing thickness along the axis toward the free end and/or a greatest thickness proximate the base 128 relative to a thickness of the body proximate the free end 132. For example, a thickness 134a of the permanent magnet 112 may be larger than a thickness 134b of the permanent magnet 112. The thickness may be measured generally transverse (e.g., orthogonal) to the general direction of the permanent magnet 112 at that point. Additionally or alternatively, the thickness may be measured generally orthogonal to the z-axis in some embodiments. A magnitude of a magnetic field of the permanent magnet may be greatest proximate the base 128 relative to a magnitude of the magnetic field of the permanent magnet 112 proximate the free end 132.

Without being limited by theory, the magnetic field may attract photons toward the base 128 of the permanent magnet 112. For example, the permanent magnet 112 may create a real or synthetic magnetic field. In some embodiments, the synthetic magnetic field can cause photons to rotate in a vortex formation to collect a denser volume of photon packets. The photon packets may increase in density with every vortex cycle to the singular point. The solar energy conversion system 100 may cause a rotating “vortex beam” that can have a twist that changes across a length of the beam of photons.

The magnetic field of the permanent magnet 112 may be configured to increase the flux of photons incident on the solar panel 104 by attracting photons having a first spin state toward the base of the permanent magnet. As noted below, in some embodiments the ISHE generator 124 may be configured to change a spin state of the photons so that additional photons are incident on the solar panel 104 and/or so that the photons are incident at a modified angle on the solar panel 104, thereby increasing absorption of the photons. For example, the ISHE generator 124 may put the photons into a controlled spin to put them into a time reference that increases a density of photons. This controlled spin can increase a density of photons incident on the solar panel 104 and thereby increase the flux and, by extension, a conversion of light power into electrical power.

The solar energy conversion system 100 can further include an electromagnetic receiver 116. The electromagnetic receiver 116 can be configured to generate electromagnetic waves that resonate with the magnetic field of the permanent magnet. The resonant electromagnetic waves may be able to direct photons toward the permanent magnet 112 to increase the flux of photons that are attracted toward the base 128 of the permanent magnet 112. The resonant electromagnetic waves may produce a resonance near the permanent magnet 112 that helps attract and/or capture additional photons. The electromagnetic receiver 116 may thus increase the efficiency of energy conversion of the solar panel 104. The electromagnetic receiver 116 can be configured to cause emission of electromagnetic waves having a frequency of between about 1 kHz and about 100 kHz and in some embodiments between about 10 kHz and about 100 kHz. The resonance may need to be calibrated properly to avoid having a repulsive effect on photons. While electromagnetic fields, including resonant electromagnetic fields, may have attractive properties, they may also have repulsive properties.

The solar energy conversion system 100 can additionally or alternatively include an antenna 120 that is disposed along at least a portion of the permanent magnet 112. The antenna may be configured to emit the electromagnetic waves generated by the electromagnetic receiver 116. The electromagnetic waves may include radio waves, microwaves, or some other band of electromagnetic waves. The antenna 120 can be disposed on a surface of the permanent magnet 112 so that it generally tracks the helical shape of at least a portion of the permanent magnet 112. The permanent magnet 112 may have a height (along the z-axis) of between 0.2 times and about 1 times the length of the solar panel 104.

In some embodiments, the antenna 120 may additionally or alternatively be configured to detect how effective the resonant electromagnetic waves are in increasing the flux of photons. Such tracking of the effectiveness of the resonant electromagnetic waves can allow for adjustment (e.g., manual, automatic) of the frequency and/or amplitude of the resonant electromagnetic waves output by the electromagnetic receiver 116. For example, the receiver 116 may be able to receive information about the surrounding or ambient electromagnetic waves present naturally in the environment. The electromagnetic receiver 116 may be configured to emit electromagnetic waves that correspond to the electromagnetic waves in the environment, which may help with achieving and/or enhancing the resonance. The emitted electromagnetic waves may be the same as the ambient electromagnetic waves in some cases.

In some embodiments, the antenna 120 is configured to receive data corresponding to the flux of the photons. The antenna 120 can then transmit to the electromagnetic receiver 116 a flux signal indicative of the flux of the photons. The electromagnetic receiver 116 can then determine the flux of the photons based on the flux signal. Additionally or alternatively, the antenna 120 may be configured to receive the information about the ambient electromagnetic waves noted above. In some embodiments, the receiver 116 may be configured to receive information about ambient electromagnetic waves from a different antenna other than the antenna 120.

The solar energy conversion system 100 may additionally or alternatively include one or more inverse spin hall effect (ISHE) generators 124. For example, as shown, the solar energy conversion system 100 may include four ISHE generators 124. For example, each ISHE generator 124 may include corresponding features that are disposed substantially parallel to the plane and/or to a corresponding edge of the semiconductor substrate. Other arrangements are possible. For clarity, reference to a single inverse spin hall effect generator 124 will be made herein, although a plurality of ISHE generators 124 may be included.

The ISHE generator 124 can be configured to modify a velocity of photons moving toward the base of the permanent magnet to direct the increased flux of photons toward the semiconductor substrate. For example, the ISHE generator 124 may modify the velocity of the photons by reducing a rotational velocity of the photons in a rotating vortex. Additionally or alternatively, the ISHE generator 124 may apply a drag effect on the photons. The drag effect may cause the photons to change direction as described above, which can help the photons be absorbed because a timing of their incidence is better controlled, thereby reducing loss of conversion to electricity. Additionally or alternatively, the drag effect may cause a current that can be captured by a battery (e.g., the battery 118). In some embodiments, the ISHE generator 124 can be configured to modify the velocity of the photons moving toward the base 128 of the permanent magnet 112 without requiring electrical power to the plurality of electrical leads 152, 156 (see below).

The ISHE generator 124 can be connected to and/or extend along the frame 108 of the solar panel. For example, as shown, the ISHE generator 124 may be disposed on an interior edge of the frame 108. The ISHE generator 124 can generate a flow of electrons in response to a spin current (e.g., from a spin state) of electrons. For example, the semiconductor substrate may be configured to generate a spin current in response to interaction with the photons (e.g., incident photons). The flow of electrons can be used to power elements of the solar energy conversion system 100 (e.g., the electromagnetic receiver 116) and/or to charge a battery 118.

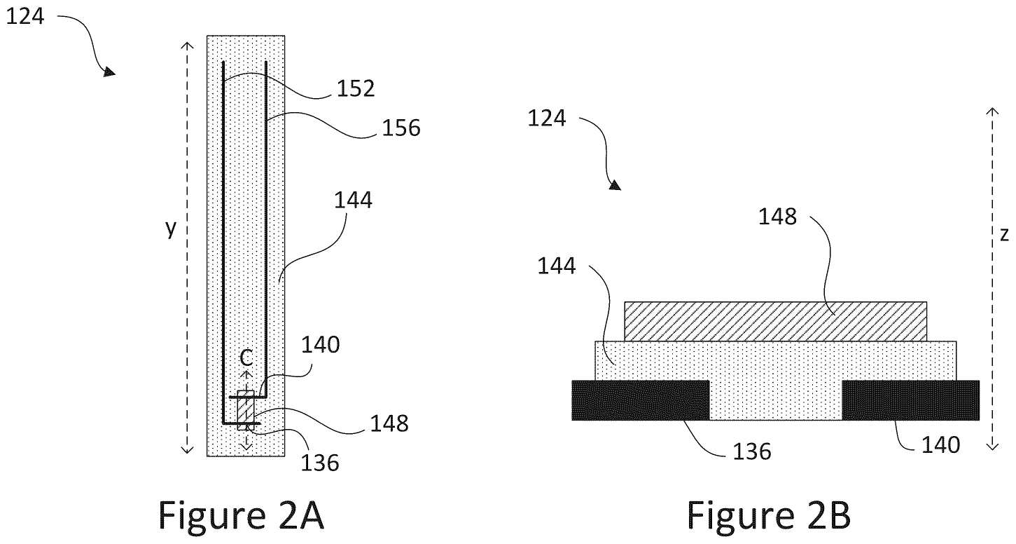

As shown in FIG. 1A, the solar energy conversion system 100 may include a photovoltaic panel controller 115 that is connected to the solar panel 104 and to the battery 118. For example, the photovoltaic panel controller 115 may be between the solar panel 104 and the photovoltaic panel controller 115. For embodiments with a plurality of ISHE generators 124, each ISHE generator 124 may be separately or independently operated and/or controlled by the photovoltaic panel controller 115. Additionally or alternatively, each ISHE generator 124 may separately and/or independently charge the battery 118. Additional features of the ISHE generator 124 are described below, such as in reference to FIGS. 2A and 2B.

FIG. 1C shows how the magnetic field of the permanent magnet 112 can draw in additional photons 160, thereby increasing a flux of the photons 160. The photons 160 that are near the solar energy conversion system 100 but would otherwise not naturally interact with the solar panel 104 (not shown in FIG. 1C) can be attracted or otherwise deflected toward the solar panel 104. As shown, the photons 160 may be attracted toward the solar panel 104 due to a funneling effect created by the magnetic field of the permanent magnet 112. For example, the magnetic field of the permanent magnet 112 can attract photons (e.g., real photons) toward the base 128 of the permanent magnet 112. The magnetic field of the permanent magnet 112 and/or associated resonance effects discussed herein can attract photons from outside of the area or surface area of the planar surface of the solar panel along which the semiconductor substrate extends to capture photons. The funneling effect may be up to 30 cm in any direction from an edge of the solar panel 104. Without being limited by theory, the photons 160 may be directed generally toward a center of the permanent magnet 112 (e.g., toward a central region of the solar panel 104 over which the permanent magnet 112 is centered). In this way, the solar energy conversion system 100 may be able to capitalize on a three-dimensional features and motion of photons 160 near the solar energy conversion system 100.

Without being limited by theory, the solar energy conversion system 100 may be able to attract virtual photons 164. The virtual photons 164 may be generated by and/or attracted to the center of the permanent magnet 112 in response to the magnetic field of the permanent magnet 112. The antenna 120 can be configured to emit the electromagnetic waves to resonate with the magnetic field of the permanent magnet (and/or the ferromagnet 148 described below), thereby programming virtual photons into real photons that can interact with the solar panel 104. The antenna 120 may be configured to emit the electromagnetic waves to resonate with the magnetic field of the permanent magnet 112 thereby generating additional virtual photons. The magnetic field of the permanent magnet 112 may cause the additional virtual photons to be programmed into additional real photons. For example, the electromagnetic waves and/or the resonance may program the virtual photons into real photons. Additionally or alternatively, the permanent magnet 112 may attract the virtual photons toward the solar panel 104. As noted above, the resonance should be properly calibrated.

The virtual photons may not be attracted by the magnetic field toward the substrate if the resonance is too strong or improperly calibrated. For example, too much resonance may overcome the magnetic field attraction of the photons toward the panel that may otherwise be achieved. This may be due in part to quantum features of the photons. The virtual photons may be programmed and/or turned into real photons in response to being observed. Additionally or alternatively, the virtual photons may remain virtual photons so long as they are unobserved. The attractive force of the virtual photons may be used to control or manipulate a pathway of the virtual photons.

As shown in FIG. 1C, the virtual photons 164 may be drawn into a vortex that rotates generally along the shape of the permanent magnet 112. Thus, the virtual photons 164 may form a swirling vortex. The swirling vortex itself may form a helical shape, as shown in FIG. 1C. These additional virtual photons 164 may further increase the flux of total photons that interact with the solar panel 104. Additionally or alternatively, the nature of the interaction may be of a higher intensity of photons (e.g., like a waterfall) than a natural showering of photons over time.

FIG. 1D shows how in some embodiments the virtual photons 164 may form a cloud that generally surrounds the permanent magnet 112. Although the virtual photons 164 are shown only in the outline of a cross-section of the clouds for clarity purposes, the cloud of virtual photons 164 may create a 3-dimensional form (e.g., cone, pyramid, frustum) that encompasses the permanent magnet 112 and generally tracks a magnetic field of the permanent magnet 112.

FIG. 2A shows a top view of an example ISHE generator 124, according to one embodiment. FIG. 2B shows a side view of the portion of the ISHE generator 124 of FIG. 2A, along the cross-section C. The ISHE generator 124 may be a ISHE generator 124 used in the solar energy conversion system 100 described above and/or in elements (e.g., aerodynamic system 600) described below.

The ISHE generator 124 can include a positive electrical coupling 136, a negative electrical coupling 140, a polymer layer 144, a ferromagnet 148, and plurality of electrical leads 152, 156. The polymer layer 144 may be disposed axially above and/or between the positive electrical coupling 136 and the negative electrical coupling 140. This arrangement may prevent a flow of electricity between the positive electrical coupling 136 and the negative electrical coupling 140, at least not directly. The polymer layer 144 can include a dielectric, such as a ceramic. The dielectric may be configured to increase resistance of a flow of electricity between the ferromagnet 148 and the positive or negative electrical couplings 136, 140 via the polymer layer 144. In some embodiments, the polymer layer 144 can include an organic semiconductor. In some embodiments, the polymer layer 144 includes silicon. The ISHE generator 124 may generally be elongate (e.g., due to the length of the electrical leads 152, 156). As discussed below, the positive electrical lead 152 may be configured to at least partially surround other elements described herein (e.g., a vehicle shell, an electrical motor, a permanent magnet, etc.).

The ferromagnet 148 can be disposed or otherwise coupled axially above the polymer layer 144. The ferromagnet 148 may be configured to generate a second magnetic field. The polymer layer 144 may separate the positive and negative couplings 136, 140 from each other and separates the ferromagnet 148 from each of the positive and negative couplings 136, 140, such as shown in FIG. 2B. A distance between the ferromagnet 148 and the positive and/or negative electrical couplings 136, 140 may be less than 0.1% of the thickness of the semiconductor substrate, less than 1% of the thickness of the semiconductor substrate, and/or less than 5% of the thickness of the semiconductor substrate. The positive and negative couplings 136, 140 may each comprise carbon. For example, one or more of the positive and negative couplings 136, 140 may include graphene.

In response to the second magnetic field applied to the polymer layer 144, the ferromagnet 148 may be configured to modify a velocity of photons to increase absorption of the photons by the semiconductor substrate of the solar panel 104. Additionally or alternatively, the polymer layer 144 may comprise a substance that is configured to modify the velocity of the photons. For example, as noted herein, the polymer layer 144 may include a ceramic, which may be configured to accelerate (e.g., decelerate) the photons by, for example, changing their angle of incidence, thereby increasing their absorption by the solar panel 104 and thus increasing the conversion of light energy to electrical energy. The modified velocity of the photons may be an acceleration of the photons about a curved trajectory. Additionally or alternatively, the ferromagnet 148 may be configured to change an angle of incidence of the photons onto the semiconductor substrate. This changed angle of incidence may increase an absorption of the photons for conversion to electricity. Accordingly, in some embodiments, the ISHE generator 124 may be configured to increase a conversion of photons incident on the solar panel 104 to electricity.

In some embodiments, the ISHE generator 124 may be configured to modify a spin of photons that are incident on the solar panel 104. This may put the photons in a time reference, which may increase a density of incident photons.

The ISHE generator 124 may additionally or alternatively include a plurality of electrical leads 152, 156. The positive electrical lead 152 and the negative electrical lead 156 may each be coupled to corresponding couplings of the positive and negative electrical couplings 136, 140. Each of the plurality of electrical leads 152, 156 may be disposed substantially parallel to the x-y plane and/or parallel to an edge of the semiconductor substrate.

The ferromagnet 148 may generate the second magnetic field, which may be configured to generate electricity within the plurality of electrical leads 152, 156. For example, each of the electrical leads 152, 156 can be configured to transmit electrical current orthogonal to the second magnetic field produced by the ferromagnet 148. In response to the second magnetic field, the positive and negative electrical couplings 136, 140 can be configured to generate a flow of electrons along the plurality of electrical leads 152, 156 in response to a spin current of electrons generated within the polymer layer 144.

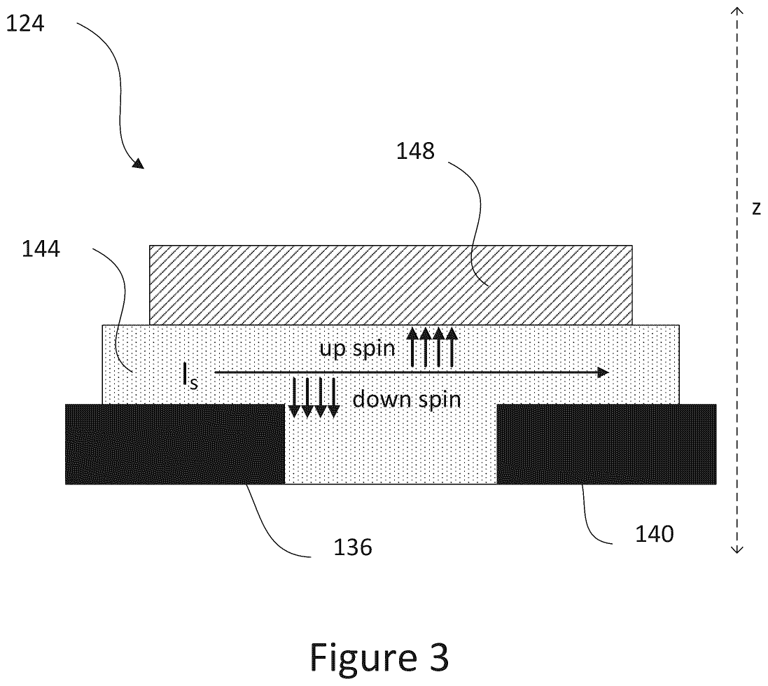

FIG. 3 shows an example implementation of the ISHE generator 124 for creating spin current. Electrons within the polymer layer 144 may be separated by their spin. For example, up-spin electrons may be attracted toward the ferromagnet 148 while down-spin electrons may be directed toward a based of the ISHE generator 124. In the presence of the second magnetic field produced by the ferromagnet 148, the electrons may create a spin current I_{S} within the polymer layer 144 between the positive electrical coupling 136 and the negative electrical coupling 140. The spin current I_{S} may be in response to the difference in spin between the upper electrons and the lower electrons in the polymer layer 144. The spin separation may be created in one or more ways. For example, without being limited by theory, the photons interacting with the magnetic field of the permanent magnet may create the spin separation. The spin current I_{S} may be helpful to powering elements described herein and/or charging a battery (e.g., the battery 118). Thus, the ISHE generator 124 may be helpful in reducing energy output of other electrical elements of the solar energy conversion system 100 and/or of the acrodynamic system 600 described below.

Additionally or alternatively, the polymer layer 144 may be excited by electromagnetic waves (e.g., microwaves). The polymer layer 144 may be magnetized with a magnetization vector M that differs from a magnetic field created by the electromagnetic waves. This difference in vector angle between M and the electromagnetic waves can create an oscillation that drives up-spin electrons to one location and down-spin electrons to a different location.

Other methods of creating the separation of electrons by spin are possible. For example, a charge current may be applied to the polymer layer 144 (e.g., from the battery 118). The charge current may be applied along a direction that, in combination with the magnetic field of the ferromagnet 148, creates a separation of spins among the electrons. This may be possible, for example, if the polymer layer 144 does not include inversion symmetry.

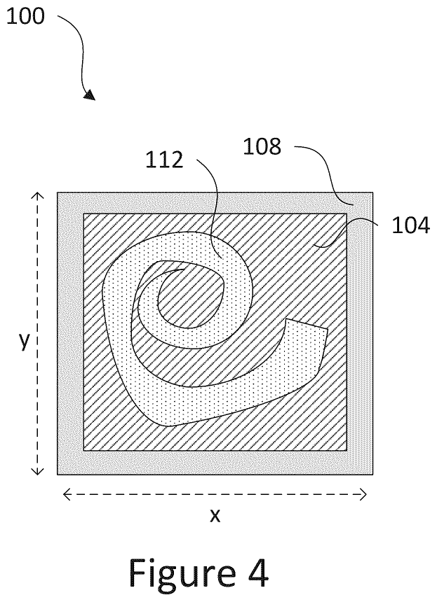

FIG. 4 shows another example of a solar energy conversion system 100 that does not include an antenna 120, an ISHE generator 124, or an electromagnetic receiver 116. Other alternatives to the solar energy conversion system 100 described above are possible.

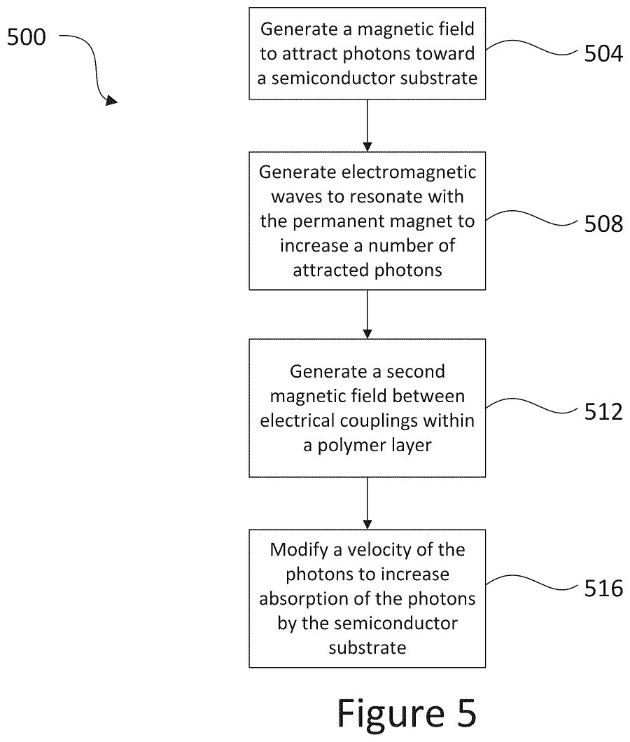

FIG. 5 shows an example method 500 that may be performed by an example solar energy conversion system 100 described herein. For example, at block 504 a system (e.g., the solar energy conversion system 100, the electromagnetic receiver 116) may generate a magnetic field using a permanent magnet (e.g., using the permanent magnet 112) to attract photons toward a semiconductor substrate. At block 508, the system may generate electromagnetic waves to resonate with the permanent magnet to increase a number of attracted photons. At block 512, the system can generate a second magnetic field using a second magnet (e.g., the ferromagnet 148) between electrical couplings within a polymer layer (e.g., the polymer layer 144). At block 516, the system can modify a velocity of the photons to increase absorption of the photons by the semiconductor substrate. The modified velocity may include any modification of velocity described above, such as changing an angle of incidence of the photons at the semiconductor substrate.

### Fluid Dynamic Systems

Ultrasound can be used to reduce aerodynamic or other fluid dynamic (e.g., hydrodynamic) drag. This reduction in drag can enhance energy conservation by using ultrasound to alter the structure of boundary layers. A continuous thin sheet or pocket of ultrasound can be radiated transversely into the boundary layer of the fluid parallel or next to a surface of an object, such as an aircraft wing or automobile shell carrying that boundary layer, to repel the fluid from interacting directly with the corresponding surface of the object, thereby minimizing pressure and turbulent flow proximate or at the corresponding surface of the object.

Described herein are embodiments for improving ways of helping keep that the ultrasound sheet or pocket under (or over) the structure. The embodiments may compensate for downstream drift of the sheet with fixed fluid dynamic structures flow by transmitting it in a forward direction in proportion to the velocity of the flow. The ultrasonic sheet may be applied as periodic strips spaced at predetermined downstream intervals.

In order to decrease the amount of acoustical energy required to implement the techniques of the system and to operate in a more efficient way, the electromagnetic field from electric motors can be used to help with the ultrasound transmission, which may be modulated with audio frequencies from installed devices.

The audio frequency can be tuned to match various fluid dynamic interactions, which may be programmed into an onboard system to tune automatically as velocity and density changes.

By controlling the turbulence and onset of separation flow characteristics of a fluid flow higher fluid dynamic efficiency can be achieved. Ultrasonic transducers can be positioned at specific points on the fluid dynamic shell of the object (e.g., vehicle) and set to specific standards to react appropriately to the affected fluid dynamic boundary layer.

The system can take advantage of certain unique properties and advantages associated with ultrasound. For example, ultrasonic acoustic energy can be readily focused, or directed, at its intended point of interaction, thus requiring a less powerful and less expensive sound generator than previously required. A further advantage of using ultrasound modulated with audible sound as opposed to using audible sound by itself is the relative ease of generating large sound intensities or oscillating air pressure signals with small sized sound transducers. Further, since the rate of absorption of acoustic energy into the boundary flow may increase with increasing frequency, ultrasound may further decrease the acoustic energy required.

The frequency of ultrasound typically does not naturally match the characteristic frequency of the turbulent boundary layer although the wavelength of ultrasound may match the length dimensions of the turbulence structure in the boundary layer. This spatial match can enhance the interaction between the acoustic energy and the formation of the boundary layer eddies and smaller scale turbulence features.

The transmitted acoustic waves can be substantially matched to the spatial and temporal frequency characteristics of the dynamic characteristics of the turbulent boundary layer. The spatial match may be provided since ultrasonic wave lengths are of the order of millimeters and centimeters, which is substantially the same as the typical dimensions of the discrete turbulence structure. Because the characteristic frequencies of the turbulent boundary layer are in the audible range, a mismatch normally will occur since the frequency of the spatial acoustic signal is of a single frequency, typically outside the audible range. The signals can be matched to maximize the drag reduction feature by modulating the ultrasonic transmissions with audible frequencies and by tuning the audio frequency to match various operating conditions.

For example, piezoelectric ceramic transducers (piezoceramic transducers) that can emit high intensity focus ultrasound (HIFU) may be used. Example ranges of specifications include:
Outer diameter up to 8-inch sections
Electrode Material: silver, nickel, titanium, gold, etc.
Electrode Patterns: parallel, wrap around and other customized patterns.
Rated Power Density: 7 W/cm² (input electrical power) we can expect outputs from 10 kHz to 10 MHz

The HIFU technology can improve the energy conversion efficiency in deployed devices driven by low voltage and low power.

The electromagnetic field can be converted directly into electrical current, such as by using the Inverse Spin Hall Effect, which can utilize the vehicle's motor electromagnetic field emissions to offset energy consumption to energize the piezoceramic transducers and amplifier to operate the described systems herein.

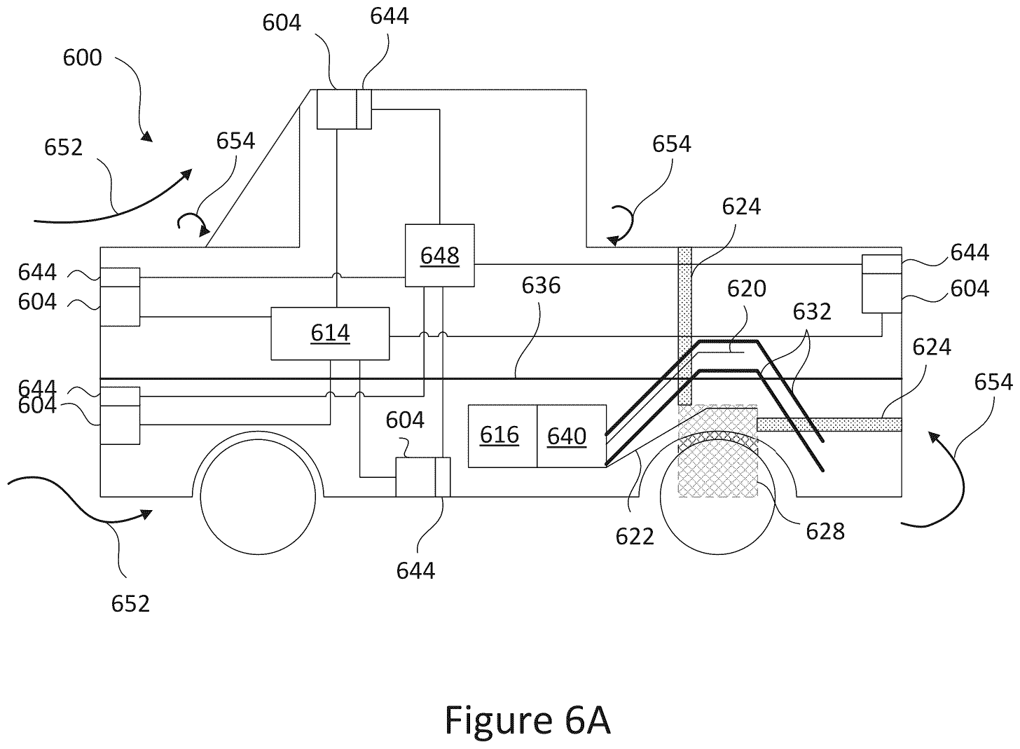

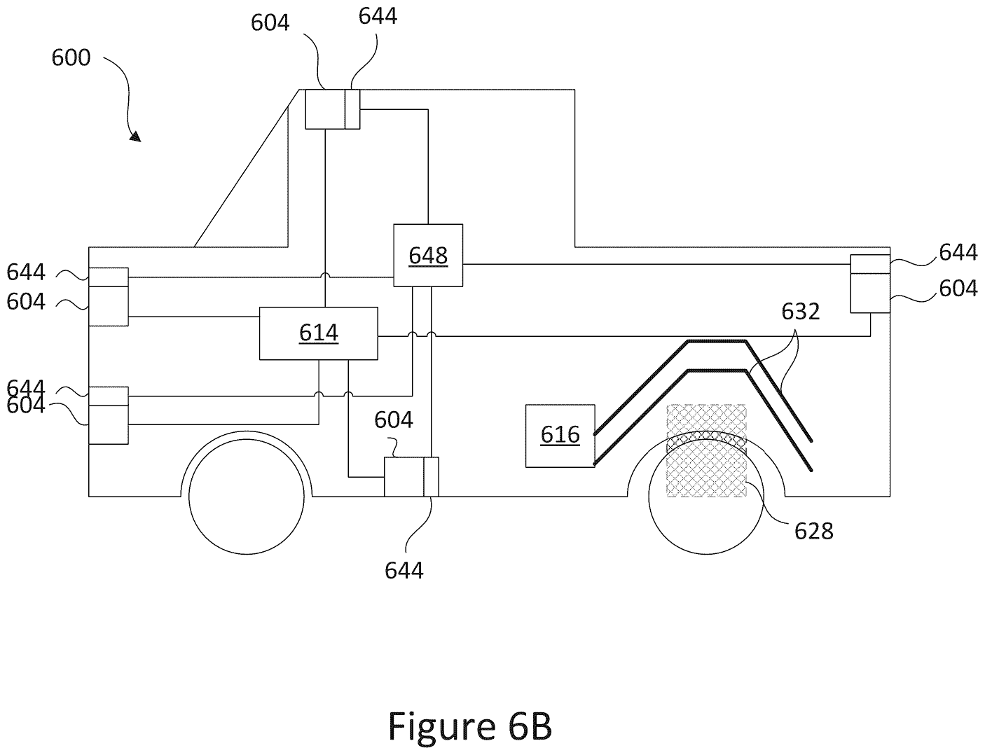

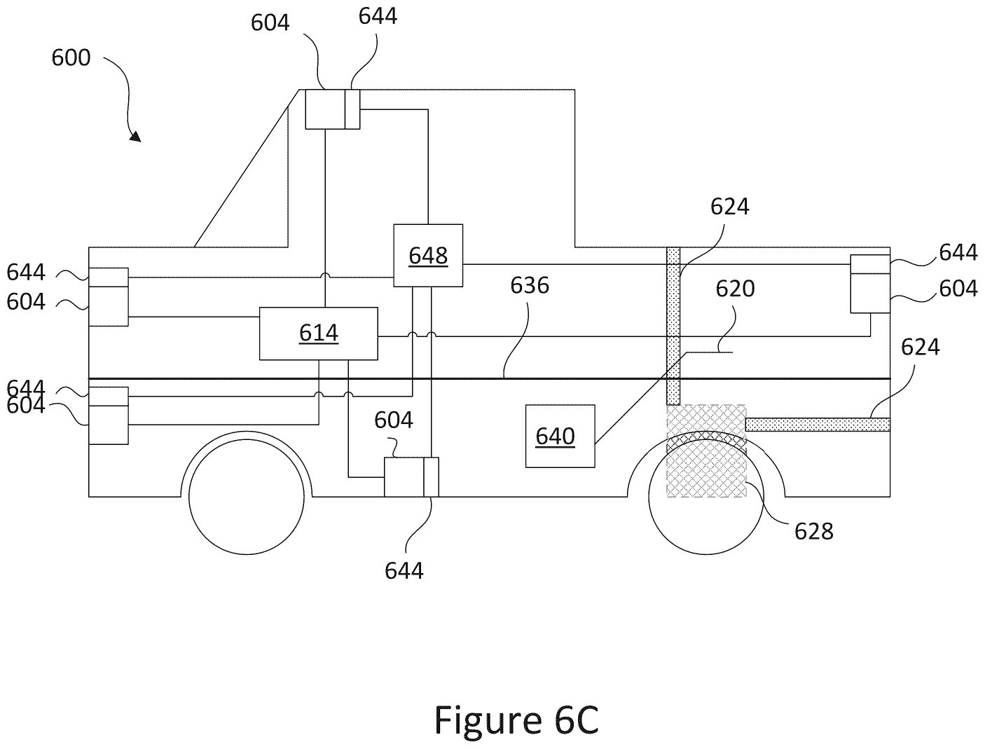

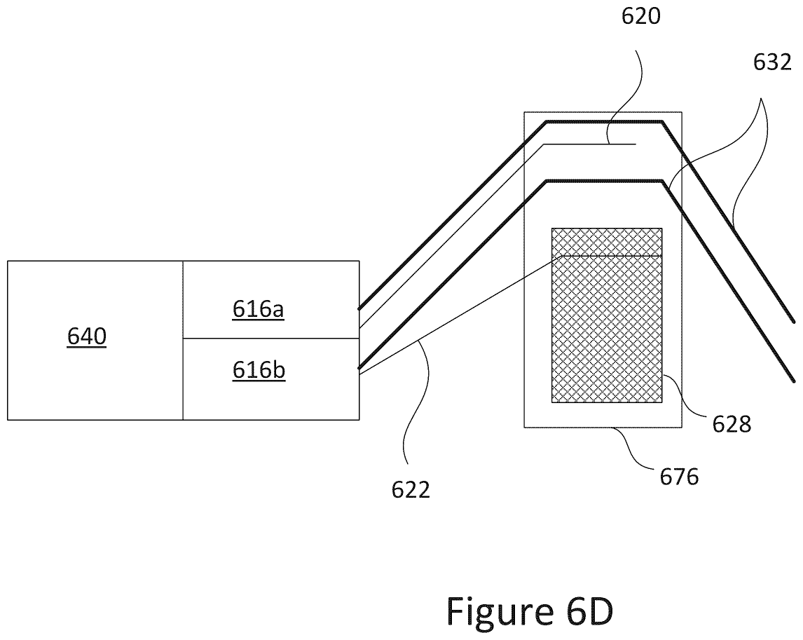

FIG. 6A shows an example fluid dynamic system 600 that is configured to reduce fluid drag on a moving object, such as a vehicle (e.g., car, plane, boat, rocket, etc.), according to one embodiment. As shown in FIG. 6A, the fluid dynamic system 600 is an aerodynamic system applicable to a vehicle, but other systems are possible (e.g., wind turbine, water turbine, wing, etc.).

The fluid dynamic system 600 can include one or more transducers 604, one or more pressure sensors 644, an energy source 614, an inverse spin hall effect (ISHE) generator 616, one or more antennae 620, 622, 636, an electromagnetic receiver 640, and/or a controller 648. The transducers 604 may be ultrasound transducers, such as piezoelectric (e.g., piezoceramic) transducers. The transducer 604 may be configured to generate ultrasound waves. Each of the transducers 604 can be positioned proximate to an exterior surface of the moving object. The transducers 604 may convert one source of energy from the energy source 614 to ultrasound waves. The energy source 614 may be native to the object (e.g., a vehicle battery). The energy source 614 may include a radio frequency (RF) generator (e.g., microwave generator) that is connected to each of the transducers 604. The RF generator may be configured to emit microwaves or some other radio wave frequency waves. The transducers 604 can be configured to receive the microwaves (or other waves) and convert them to ultrasound waves and emit the ultrasound waves toward the fluid.

The transducers 604 can emit the ultrasound waves toward fluid (e.g., ambient airflow, water) proximate the exterior surface of the object. The fluid may exert pressure on the exterior of the object as the object moves through fluid. The ultrasound waves emitted by the transducers 604 can convert turbulent flow 654 of the fluid to laminar flow 652 proximate the exterior of the object to reduce pressure exerted by the fluid on the exterior of the object moving through fluid. This conversion can reduce fluid drag on the object.

The controller 648 may be configured to receive the pressure signal from each of the pressure sensors 644. The controller 648 may use one or more of the pressure signals to determine a target ultrasound wave for a corresponding transducer 604. The controller 648 can cause the corresponding pressure sensors 644 to emit the target ultrasound waves to convert the turbulent flow 654 of the fluid to laminar flow 652 proximate the exterior of the object. This conversion can reduce fluid drag on the object. It may be valuable, for example, to equalize a pressure of fluid flow at a top and at a bottom of the object.

The pressure sensors 644 can each be configured to be positioned proximate to the exterior surface of the object. For example, the pressure sensors 644 may be disposed near (e.g., adjacent) a corresponding transducer 604. In this way, the pressure sensor 644 can detect a pressure near the transducer 604. The transducers 604 may be disposed near surfaces of the object where turbulent flow 654 is expected. Accordingly, the pressure sensor 644 may be configured to also track a pressure near turbulent flow 654 of the object. The pressure sensors 644 can detect a pressure of the fluid at a location of a corresponding transducer 604 and generate a pressure signal corresponding to the pressure at the location. Additionally or alternatively, the pressure sensors 644 can include an upper plurality of pressure sensors 644 and a lower plurality of pressure sensors 644. At higher speeds, the lower plurality of transducers 604 may need to provide a higher ultrasound wave output.

The controller 648 can be configured to receive first pressure signals from each of the upper plurality of pressure sensors 644 and to receive second pressure signals from each of the lower plurality of pressure sensors 644. The controller 648 may be configured to determine first target ultrasound waves based on the first pressure signals for transducers 604 corresponding to each of the upper plurality of transducers 604. The controller 648 may be configured to determine second target ultrasound waves based on the second pressure signals for the transducers 604 that correspond to each of the lower plurality of transducers 604. The controller 648 may modify (e.g., increase) a voltage applied to the transducers 604. The target ultrasound waves described above may include the first and second target ultrasound waves.

The controller 648 may be configured to cause the corresponding transducers 604 to emit the first and second target ultrasound waves. The first target ultrasound waves may have at least one of a higher amplitude and/or frequency than do the second target ultrasound waves. For example, each of the target ultrasound waves may have a higher amplitude and/or frequency in response to the speed of operation of the electric motor being higher. Additionally or alternatively, the target ultrasound waves may have the higher amplitude and/or frequency in response to the pressure of the fluid (e.g., ambient airflow, water) at the location of the corresponding transducer 604 being higher. The target ultrasound waves may modulate the amplitude and/or the frequency of the electromagnetic field in response to a different frequency and/or amplitude of the electromagnetic field from the electric motor 628. For example, the target ultrasound waves may have a higher amplitude and/or frequency in response to a higher frequency and/or amplitude of the electromagnetic field in response to the electric motor 628 operating at a higher speed.

In some embodiments, the transducers 604 may include one or more subsets of transducers 604. For example, the transducers 604 may include an upper plurality of transducers 604 and a lower plurality of transducers 604. Each of the upper plurality of transducers 604 may be configured to be positioned proximate to an upper surface of the vehicle with lower pressure from fluid flow with the object moving through fluid. Additionally or alternatively, each of the lower plurality of transducers 604 may be configured to be positioned proximate to a lower surface of the object with higher pressure relative to the lower pressure from fluid as the vehicle moves through the fluid.

In some embodiments, the electromagnetic receiver 640 may be configured to determine a resonance adjustment factor based on the pressure signal. The electromagnetic receiver 640 may transmit the resonance adjustment factor to the antenna 620, 622, 636 and cause the antenna 620, 622, 636 to generate the resonance electromagnetic waves based on the resonance adjustment factor. The resonance adjustment factor may take into account a difference between a target resonance and the electromagnetic field produced by the electric motor 628. The resonance adjustment factor may be higher in response to a higher speed of operation of the electric motor and/or may be lower in response to a lower speed of operation of the electric motor 628.

The ISHE generator 616 can be configured to be positioned in a way that can help capture energy from an electric motor 628 of the moving object. For example, the ISHE generator 616 can be positioned at least partially on and/or about the electric motor 628 and/or at least partially on and/or about a shell or a chassis of the object. FIG. 6D shows and example of the ISHE generator 616 (e.g., the electrical leads 632) being disposed at least partially around a casing of the electric motor 628. For example, the ISHE generator 616 may be positioned proximate an edge of a casing about the electric motor 628. The casing may be electrically and/or magnetically conductive. The ISHE generator 616 can be configured to generate electric power from an electromagnetic field generated by the electric motor 628 of the object. The generated power from the ISHE generator 616 may include direct current (DC). In this way, the electromagnetic field may be at least partially recycled.

The ISHE generator 616 can include one or features of the ISHE generator 124 described above. For example, the ISHE generator 616 may include a positive electrical coupling and a negative electrical coupling (not shown in FIG. 6A). in some embodiments, the ISHE generator 616 includes a ferromagnet that generates a second electromagnetic field (different from the electromagnetic field generated by the electric motor 628). The second electromagnetic field may modify the electromagnetic field generated by the electric motor 628.

In some embodiments, the ISHE generator 616 includes a polymer layer (not shown in FIG. 6A). The polymer layer may include one or more features of the polymer layer 144 described above. For example, the polymer layer may be disposed on and between each of the positive and negative electrical couplings. The polymer layer can separate the positive and negative couplings from each other and/or can separate the ferromagnet from each of the positive and negative couplings. The polymer layer may include a dielectric that increases resistance of a flow of electricity between the ferromagnet and the positive or negative electrical couplings via the polymer layer. The positive and negative electrical couplings may be configured to generate the flow of electrons along the plurality of electrical leads in response to a spin state of electrons within the polymer layer.

The ISHE generator 616 can also include a plurality of electrical leads 632 that are each coupled to corresponding of the positive and negative electrical couplings. Each of the electrical leads 632 may be disposed about the electric motor 628 of the object. Each of the electrical leads may be configured to interact with the polymer layer and/or with the electromagnetic field generated by the electric motor 628 (which may be modified by the ferromagnet). In response to an interaction of the electrical lead 632 with the polymer layer and/or with the modified electromagnetic field, the positive and negative electrical couplings may be configured to generate a flow of electrons along the electrical lead 632. The flow of electrons may be a spin current generated in response to a spin state of electrons within the polymer layer. The current generated may be used to power the transducers 604, the pressure sensors 644, and/or charge a battery of the object (e.g., the energy source 614) using the flow of electrons generated. For example, the flow of electrons may charge a vehicle battery. As shown in FIG. 6A the electrical lead 632 may be disposed on a shell of the moving object, but the electrical lead 632 may additionally or alternatively be positioned interior of the shell (e.g., about a motor casing of the electric motor 628) (see, e.g., FIG. 6D). A battery may be connected to the ISHE generator 616. The battery may be configured to store the electrical power generated by the ISHE generator 616 (e.g., from DC produced by the ISHE generator 616). The fluid dynamic system 600 may include a DC regulator connected to the ISHE generator 616. The DC regulator may be configured to charge the battery from power generated by the ISHE generator 616.

The ISHE generator 616 may include one or more antennae 620, 622, 636. For example, the ISHE generator 616 may include a motor casing antenna 620. The motor casing antenna 620 may be positioned at least partially about a casing of the electric motor 628 of the object. As noted above, the motor casing may be electrically conductive, and the motor casing antenna 620 may connected to the electrically conductive casing. The antenna 620, 622, 636 may be configured to be positioned toward a center of the electric motor 628 or of the motor casing.

Additionally or alternatively, the ISHE generator 616 may include a motor antenna 622. The motor antenna 622 may be positioned on or near the electric motor 628. Additionally or alternatively, the ISHE generator 616 can include a vehicle antenna 636. The vehicle antenna 636 may be positioned at least partially about an exterior of the object (e.g., a shell of a vehicle). As shown, the vehicle antenna 636 can extend along an axis of movement and/or along a longitudinal axis of the object. The antenna 620, 622, 636 may be configured to detect an electromagnetic field emitted by the electric motor 628 and/or to generate a field signal indicative of the electromagnetic field thereof. As shown in FIG. 6A the motor casing antenna 620 may be disposed on an exterior (e.g., shell) of the moving object, but the motor casing antenna 620 may additionally or alternatively be positioned interior of the shell (e.g., about a motor casing of the electric motor 628) (see, e.g., FIG. 6D). The vehicle antenna 636 may be configured to detect resonance on the shell of the object. This information can be used to better drive the transducers 604. The resonance may include electromagnetic field and/or vibrations in the shell, which can include kinetic energy to power electronics, such as transducers as discussed herein.

The ISHE generator 616 may include a plurality of ISHE generators as described above. For example, each may be positioned proximate an edge of the electric motor 628 and/or proximate an edge of a casing about the electric motor 628. The antenna 620, 622, 636 may be configured to be positioned between at least two of the ISHE generators.

The electromagnetic receiver 640 can be configured to receive the field signal from the antenna 620, 622, 636. The electromagnetic receiver 640 may determine, based on the field signal, resonance electromagnetic waves that can resonate with the electromagnetic field emitted by the electric motor 628. The resonance electromagnetic waves may be the same as or different from the electromagnetic field generated by the electric motor 628. The electromagnetic receiver 640 can be configured to cause the antenna 620, 622, 636 to emit the resonance electromagnetic waves toward the shell or the chassis of the object (e.g., chassis of the vehicle).

The controller 648 may be configured to receive the field signal indicative of the electromagnetic field from the antenna 620, 622, 636 and, in response to a higher amplitude and/or frequency of the electromagnetic field emitted by the electric motor 628, to determine target ultrasound waves having a higher amplitude and/or frequency corresponding to the higher amplitude and/or frequency of the electromagnetic field.

In some embodiments, the fluid dynamic system 600 includes a plurality of antennae 620, 622, 636. The electromagnetic receiver 640 may be configured to receive the field signal from a second antenna of the antennae 620, 622, 636. The electromagnetic receiver 640 may be configured to cause the second antenna to emit the resonance electromagnetic waves toward the shell or the chassis of the vehicle. The second antenna may be a radio antenna of (e.g., native to) the vehicle. The electromagnetic receiver 640 may be configured to cause the second antenna to emit the resonance electromagnetic waves toward the shell or the chassis of the vehicle.

The electromagnetic field emitted by the electric motor 628 may be based on a speed of operation of the electric motor. For example, the electromagnetic field may have a higher amplitude and/or frequency at higher speeds than at lower speeds. Additionally or alternatively, the resonance electromagnetic waves may have a higher frequency and/or amplitude in response to the higher amplitude/frequency of the electromagnetic field emitted by the electric motor 628 (e.g., in response to running at higher speeds). For example, in response to the electric motor operating at a higher speed, thereby causing a higher frequency of the electromagnetic field emitted by the electric motor 628, the resonance electromagnetic waves may include a higher frequency. The higher frequency may be correspondingly higher based on the speed of the electric motor 628. In some embodiments, resonance from the electromagnetic field and the resonance electromagnetic waves in the shell or the chassis of the vehicle may be sufficient in some cases to fully power the transducers 604 without power output from the energy source 614 (e.g., microwave generator). The resonances electromagnetic waves may include radio waves and/or microwaves.

In some embodiments, the fluid dynamic system 600 can include one or more rods 624 that are configured to connect to the shell or the chassis of the object and to the electric motor 628. For example, the rods 624 may connect between the shell of the vehicle and the electric motor 628 (or a casing of the electric motor 628). The rod 624 may include a dielectric that prevents a flow of electricity therethrough. The rods 624 may be configured to receive the electromagnetic field generated from the electric motor and to transmit the electromagnetic field to the shell or the chassis of the object. In some embodiments, the antenna 620, 622, 636 can emit electromagnetic waves to the casing of the electric motor 628 to create the resonance with the electromagnetic field emitted by the electric motor 628. The resonance can be transmitted to the shell of the object via the rod 624.

The electromagnetic field at the shell or the chassis of the object (e.g., the one transmitted to the shell by the rods 624) can resonate with the resonance electromagnetic waves from the antenna 620, 622, 636. The electromagnetic field and the resonance electromagnetic waves may form a resonance at the shell or the chassis of the object. The resonance may be used to power the plurality of transducers 604. For example, the resonance may be transmitted or transferred via the shell or the chassis of the object to the transducers 604. This resonance can thus reduce power output from the energy source 614 (e.g., battery, microwave generator) for causing emission of the ultrasound waves by the transducers 604.

The resonance may transfer at least 1 Watt of power. in some embodiments, the resonance transfers at least 2 Watts, at least 3 Watts, at least 4 Watts, and/or at least 5 Watts. Additionally or alternatively, the reduction in power output from the energy source 614 may be at least 1 Watt per transducer 604, at least about 2 Watts per transducer 604, at least about 3 Watts per transducer 604, at least about 4 Watts per transducer 604, and/or at least about 5 Watts per transducer 604. The resonance may have a frequency of between about 1 kHz and 100 kHz. For example, the resonance may have a frequency of between about 1 kHz and 10 kHz. The resonance may have a frequency of between about 10 kHz and 100 kHz. In some embodiments, the frequency may be below 1 MHZ.

In some embodiments, the reduction in power output from the energy source 614 may increase as the speed of operation of the electric motor 628 increases. This may allow for higher power savings at higher speeds. Increasing speed of operation of the electric motor may increase at least one of amplitude or frequency of the electromagnetic field emitted by the electric motor 628, which may increase resonance with the corresponding resonance electromagnetic waves in the shell or the chassis of the object. For example, the electromagnetic field emitted by the electric motor 628 may in some cases correspond to the speed of operation of the electric motor 628.

Without being limited by theory, the resonance of the electromagnetic field and the resonance electromagnetic waves in the shell or the chassis of the vehicle may be such that it fully powers the transducers 604 without power output from the energy source 614 (e.g., from a battery).

FIG. 6B shows another example fluid dynamic system 600 that does not include an electromagnetic receiver 640, any rods 624, or an antenna 620, 622, 636, according to one embodiment. FIG. 6C shows another fluid dynamic system 600 that does not include a ISHE generator 616 (including electrical leads 632), according to one embodiment.

FIG. 6D shows an example fluid dynamic system 600 that includes a plurality of ISHE generators 616a, 616b and a motor casing antenna 620 disposed at least partially between the ISHE generators 616a, 616b on or about the motor casing 676. The fluid dynamic system 600 also includes an electromagnetic receiver 640 and a motor antenna 622 disposed on or about the electric motor 628.

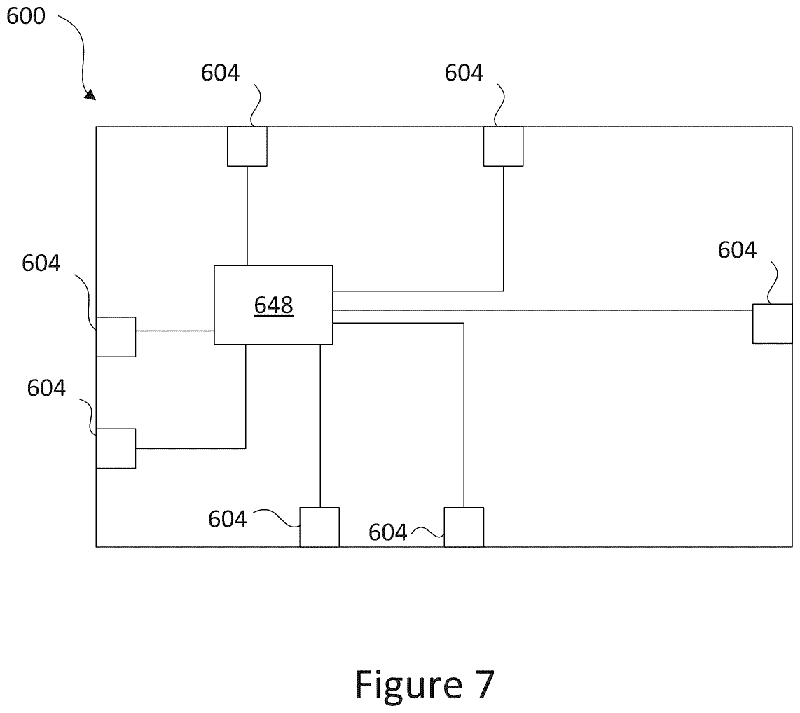

FIG. 7 shows an example of a fluid dynamic system 600 that includes a plurality of transducers 604 and a controller 648. The transducers 604 may be configured to emit ultrasound waves without input from pressure sensors described above.

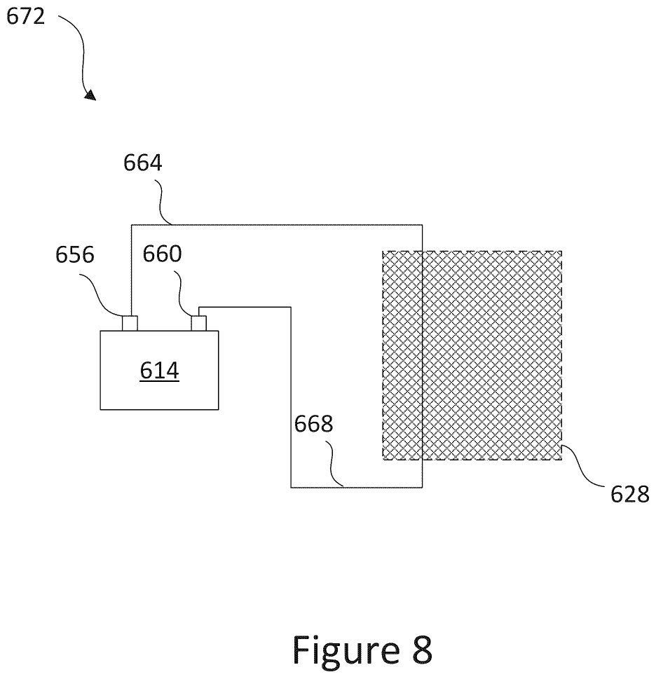

FIG. 8 shows an example inverse hall effect (IHE) generator 672, according to one embodiment. The IHE generator 672 may be implemented in the fluid dynamic system 600 additionally or alternatively to an ISHE generator 616. In some embodiments, the IHE generator 672 may be configured to be positioned at least partially about the electric motor and/or at least partially about the shell or the chassis of the vehicle. The IHE generator 672 may be positioned similarly to an ISHE generator 616 described above. The IHE generator 672 may be configured to generate electric power from the electromagnetic field generated by the electric motor 628 of the object.

The IHE generator 672 may include an energy source 614 (e.g., battery) having a positive terminal 656 and a negative terminal 660. The IHE generator 672 may include a positive electrical lead 664 and a negative electrical lead 668 that are each coupled to corresponding terminals of the energy source 614. Each of the electrical leads 664, 668 may be disposed about the electric motor 628 of the object (e.g., vehicle). Each of the electrical leads 664, 668 can be configured to interact with the electromagnetic field generated by the electric motor 628 such that in response to an interaction of the electrical leads 664, 668 with the electromagnetic field, the electrical leads 664, 668 are configured to generate electrical power. The electrical power may be used to power other elements of the system (e.g., the transducers 604) and/or generate a voltage between the positive terminal 656 and the negative terminal 660 of the energy source 614. The IHE generator 672 may generate alternating current (AC). The AC may be converted to DC as needed.

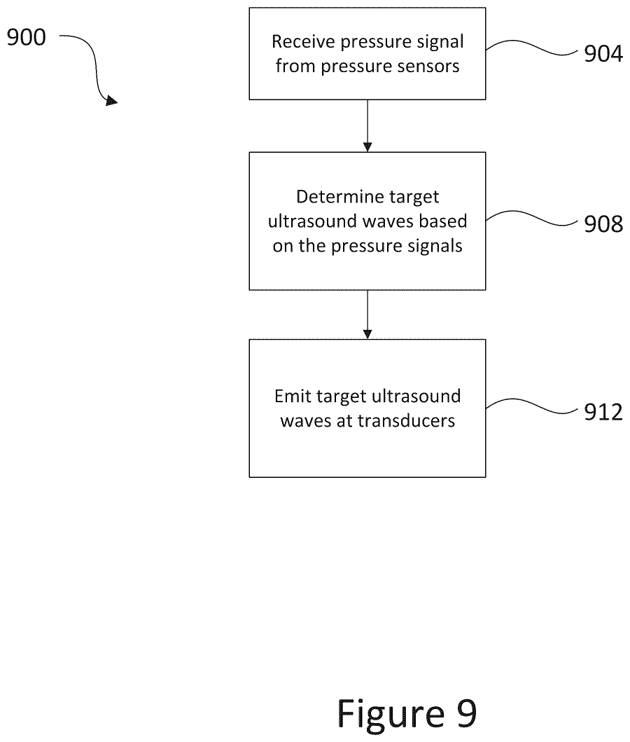

FIG. 9 shows an example method 900 that may be performed by an example fluid dynamic system 600 described herein. For example, at block 904 a system (e.g., the fluid dynamic system 600, the controller 648) may receive pressure signal from pressure sensors (e.g., the pressure sensors 644). At block 908, the system may determine target ultrasound waves based on the pressure signals. At block 912, the system can emit target ultrasound waves using transducers (e.g., transducers 604), which may be positioned on or near a surface of a moving object. Thus, the method 900 may be useful in reducing fluid drag on an object, such as by converting turbulent flow to laminar flow.

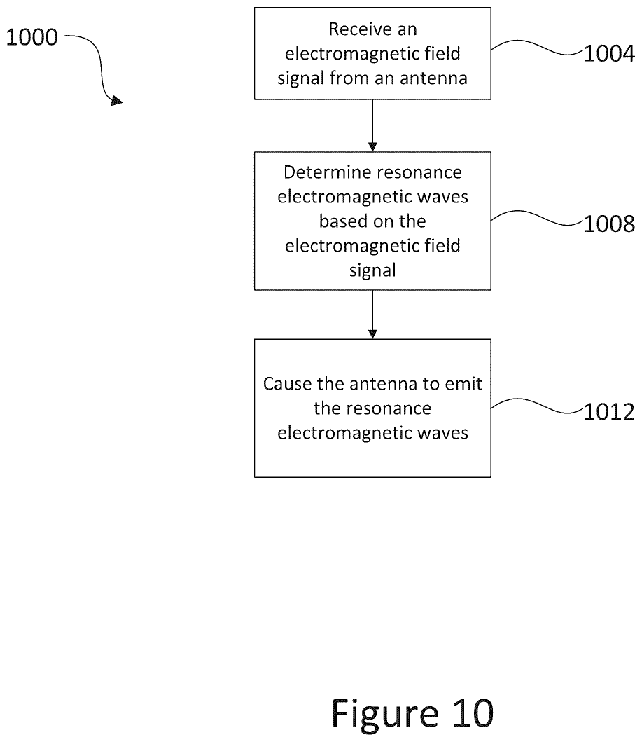

FIG. 10 shows an example method 1000 that may be performed by an example fluid dynamic system 600 described herein. For example, at block 1004 a system (e.g., the fluid dynamic system 600, the electromagnetic receiver 640) may receive an electromagnetic field signal from one or more antennae (e.g., any of antennae 620, 622, 636). At block 1008, the system may determine resonance electromagnetic waves based on the electromagnetic field signal. At block 1012, the system can cause the one or more antennae to emit the resonance electromagnetic waves. The resonance electromagnetic waves may be able to create a resonance that reduces a power output to one or more elements of the system, for example as described above. Thus, the method 1000 may be useful in reducing energy output and in conserving energy.

### Function of Logic Elements and Sequences

Depending on the embodiment, certain acts, events, or functions of any of the processes or algorithms described herein (e.g., those performed by the electromagnetic receiver 116, the controller 648, the electromagnetic receiver 640) can be performed in a different sequence, can be added, merged, or left out altogether (e.g., not all described operations or events are necessary for the practice of the algorithm). Moreover, in certain embodiments, operations or events can be performed concurrently, e.g., through multi-threaded processing, interrupt processing, or multiple processors or processor cores or on other parallel architectures, rather than sequentially.

The various illustrative logical blocks, modules, routines, user interfaces, and algorithm steps described in connection with the embodiments disclosed herein can be implemented as electronic hardware, or combinations of electronic hardware and computer software. To illustrate this interchangeability, various illustrative components, blocks, modules, and steps have been described above generally in terms of their functionality. Whether such functionality is implemented as hardware, or as software that runs on hardware, depends upon the particular application and design constraints imposed on the overall system. The described functionality can be implemented in varying ways for each particular application, but such implementation decisions should not be interpreted as causing a departure from the scope of the disclosure.

Moreover, the various illustrative logical blocks, user interfaces, and modules described in connection with the embodiments disclosed herein can be implemented or performed by a machine, such as a general purpose processor device, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor device can be a microprocessor, but in the alternative, the processor device can be a controller, microcontroller, or state machine, combinations of the same, or the like. A processor device can include electrical circuitry configured to process computer-executable instructions. In another embodiment, a processor device includes an FPGA or other programmable device that performs logic operations without processing computer-executable instructions. A processor device can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor device may also include primarily analog components. For example, some or all of the algorithms described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

The elements of a method, process, routine, or algorithm described in connection with the embodiments disclosed herein can be embodied directly in hardware, in a software module executed by a processor device (controller), or in a combination of the two, that command, control, or cause the system(s) and associated components described herein to perform one or more functions or features of the method, process, routine, or algorithm. A software module can reside in RAM memory, flash memory, ROM memory, EPROM memory, EEPROM memory, registers, hard disk, a removable disk, a CD-ROM, or any other form of a non-transitory computer-readable storage medium. An exemplary storage medium can be coupled to the processor device such that the processor device can read information from, and write information to, the storage medium. In the alternative, the storage medium can be integral to the processor device. The processor device and the storage medium can reside in an ASIC. The ASIC can reside in a user terminal. In the alternative, the processor device and the storage medium can reside as discrete components in a user terminal.

### LIST OF EXAMPLE OF NUMBERED EMBODIMENTS

The following is a list of example numbered embodiments. The features recited in the below list of example embodiments can be combined with additional features disclosed herein. Furthermore, additional inventive combinations of features are disclosed herein, which are not specifically recited in the below list of example embodiments and which do not include the same features as the embodiments listed below. For the sake of brevity, the below list of example embodiments does not identify every inventive aspect of this disclosure. The below list of example embodiments is not intended to identify key features or essential features of any subject matter described herein.
1. A solar energy conversion system configured to increase a flux of photons from solar radiation, the system comprising:
   a solar panel comprising a semiconductor substrate extending generally along a plane and configured to convert the flux of photons from solar radiation to electrical power, the solar panel comprising a frame extending about a periphery of the semiconductor substrate;
   a permanent magnet comprising a body having a helical shape extending along an axis perpendicular to the plane, the body comprising a base and a free end, the base connected to the solar panel, the helical shape having a decreasing diameter along the axis toward the free end, the helical shape of the body having a largest diameter proximate the base relative to a diameter of the body proximate the free end, the body having a decreasing thickness along the axis toward the free end, the body having a greatest thickness proximate the base relative to a thickness of the body proximate the free end, wherein a magnitude of a magnetic field of the permanent magnet is greatest proximate the base relative to a magnitude of the magnetic field of the permanent magnet proximate the free end, wherein the magnetic field attracts photons toward the base of the permanent magnet;
   an electromagnetic receiver configured to generate electromagnetic waves configured to resonate with the magnetic field of the permanent magnet to direct photons toward the permanent magnet to increase the flux of photons that are attracted toward the base of the permanent magnet;
   an antenna disposed along at least a portion of the permanent magnet, the antenna configured to emit the electromagnetic waves generated by the electromagnetic receiver; and
   an inverse spin hall effect (ISHE) generator configured to modify a velocity of photons moving toward the base of the permanent magnet to direct the increased flux of photons toward the semiconductor substrate, the ISHE connected to and extending along the frame of the solar panel, the ISHE generator comprising:
      a positive electrical coupling;
      a negative electrical coupling;
      a polymer layer disposed axially above and between the positive and negative electrical couplings, the polymer layer comprising a dielectric;
      a ferromagnet coupled axially above the polymer layer and configured to generate a second magnetic field, wherein the polymer layer separates the positive and negative couplings from each other and separates the ferromagnet from each of the positive and negative couplings, the dielectric configured to increase resistance of a flow of electricity between the ferromagnet and the positive or negative electrical couplings via the polymer layer, wherein in response to the second magnetic field applied to the polymer layer, the ferromagnet is configured to modify a velocity of photons to increase absorption of the photons by the semiconductor substrate; and
      a plurality of electrical leads each coupled to corresponding of the positive and negative electrical couplings, each of the plurality of electrical leads disposed substantially parallel to the plane and to an edge of the semiconductor substrate, each of the electrical leads configured to transmit electrical current orthogonal to the second magnetic field produced by the ferromagnet, wherein in response to the second magnetic field, the positive and negative electrical couplings are configured to generate a flow of electrons along the plurality of electrical leads in response to a spin current of electrons within the polymer layer.
2. The solar energy conversion system of Example 1, wherein the antenna is further configured to receive data corresponding to the flux of the photons and to transmit to the electromagnetic receiver a flux signal indicative of the flux of the photons.
3. The solar energy conversion system of Example 2, wherein the electromagnetic receiver is further configured to determine, based on the flux signal, the flux of the photons.
4. The solar energy conversion system of Example 3, further comprising a battery electrically connected to the ISHE generator, the battery configured to receive and store electrical energy generated from the flow of electrons along the plurality of electrical leads by the ISHE generator.
5. The solar energy conversion system of any of Examples 1-4, further comprising a plurality of ISHE generators each comprising a corresponding plurality of electrical leads disposed substantially parallel to the plane and to a corresponding edge of the semiconductor substrate.
6. The solar energy conversion system of any of Examples 1-5, wherein a distance between the ferromagnet and the positive electrical coupling is less than 1% of the thickness of the semiconductor substrate.
7. The solar energy conversion system of any of Examples 1-6, wherein each of the positive and negative electrical couplings comprises carbon.
8. The solar energy conversion system of any of Examples 1-7, wherein each of the positive and negative electrical couplings comprises graphene.
9. The solar energy conversion system of any of Examples 1-8, wherein the dielectric comprises a ceramic.
10. The solar energy conversion system of any of Examples 1-9, wherein a ratio of a width of the semiconductor substrate to a maximum height along the axis of the permanent magnet is greater than 1.
11. The solar energy conversion system of any of Examples 1-10, wherein the ISHE generator is configured to increase the flux of photons by applying a drag effect on the photons.
12. The solar energy conversion system of any of Examples 1-11, wherein the antenna is configured to emit the electromagnetic waves to resonate with the magnetic field of the permanent magnet thereby programming virtual photons into real photons.
13. The solar energy conversion system of Example 12, wherein the magnetic field of the permanent magnet attracts the real photons toward the base of the permanent magnet.
14. The solar energy conversion system of any of Examples 12-13, wherein the ferromagnet is configured to modify a velocity of the real photons, thereby increasing the flux of absorbed photons.
15. The solar energy conversion system of any of Examples 12-14, wherein the antenna is configured to emit the electromagnetic waves to resonate with the magnetic field of the permanent magnet thereby generating additional virtual photons.
16. The solar energy conversion system of Example 15, wherein, in response to the magnetic field of the permanent magnet, the additional virtual photons are programmed into additional real photons.
17. The solar energy conversion system of any of Examples 1-16, wherein the electromagnetic waves emitted by the antenna comprise radio waves.
18. The solar energy conversion system of Example 17, wherein the radio waves have a frequency of at least 1 kHz.
19. The solar energy conversion system of any of Examples 1-18, wherein the electromagnetic waves emitted by the antenna comprise microwaves.
20. The solar energy conversion system of any of Examples 1-19, wherein the magnetic field of the permanent magnet is configured to increase the flux of photons by attracting photons having a first spin state toward the base of the permanent magnet.
21. The solar energy conversion system of Example 20, wherein the magnetic field of the permanent magnet is configured to form a rotating vortex of attracted photons toward the base of the permanent magnet.
22. The solar energy conversion system of any of Examples 1-21, wherein the magnetic field of the permanent magnet is configured to form a rotating vortex of attracted photons toward the base of the permanent magnet.
23. The solar energy conversion system of Example 22, wherein the ISHE generator is configured to modifying the velocity of the photons by reducing a rotational velocity of the photons of the rotating vortex.
24. The solar energy conversion system of any of Examples 1-23, wherein the semiconductor substrate is configured to generate a spin current in response to interaction with the photons.
25. The solar energy conversion system of Example 24, wherein the ISHE generator is further configured to generate electrical power in response to the spin current generated by the semiconductor substrate.
26. The solar energy conversion system of any of Examples 1-25, wherein the base of the magnet is connected to the frame of the solar panel.
27. The solar energy conversion system of any of Examples 1-26, wherein the ISHE generator is configured to modify the velocity of the photons moving toward the base of the permanent magnet without requiring electrical power to the plurality of electrical leads.
28. A solar energy conversion system configured to increase a flux of photons from solar radiation, the system comprising:
   a solar panel comprising a semiconductor substrate extending generally along a plane and configured to convert the flux of photons from solar radiation to electrical power, the solar panel comprising a frame extending about a periphery of the semiconductor substrate;
   a permanent magnet comprising a body having a helical shape extending along an axis perpendicular to the plane, the body comprising a base and a free end, the base connected to the solar panel, the body having a decreasing diameter along the axis toward the free end, the helical shape of the body having a largest diameter proximate the base relative to a diameter of the body proximate the free end, the body having a decreasing thickness along the axis toward the free end, the body having a greatest thickness proximate the base relative to a thickness of the body proximate the free end, wherein a magnitude of a magnetic field of the permanent magnet is greatest proximate the base relative to a magnitude of the magnetic field of the permanent magnet proximate the free end, wherein the magnetic field attracts photons toward the base of the permanent magnet; and
   an inverse spin hall effect (ISHE) generator configured to modify a velocity of photons moving toward the base of the permanent magnet to direct the increased flux of photons toward the semiconductor substrate, the ISHE connected to and extending along the frame of the solar panel, the ISHE generator comprising:
      a positive electrical coupling;
      a negative electrical coupling;
      a polymer layer disposed axially above and between the positive and negative electrical couplings, the polymer layer comprising a dielectric;
      a ferromagnet coupled axially above the polymer layer and configured to generate a second magnetic field, wherein the polymer separates the positive and negative couplings from each other and separates the ferromagnet from each of the positive and negative couplings, the dielectric configured to increase resistance of a flow of electricity between the ferromagnet and the positive or negative electrical couplings via the polymer, wherein in response to the second magnetic field applied to the polymer layer, the ferromagnet is configured to modify a velocity of photons to increase absorption of the photons by the semiconductor substrate; and
      a plurality of electrical leads each coupled to corresponding of the positive and negative electrical couplings, each of the plurality of electrical leads disposed substantially parallel to the plane and to an edge of the semiconductor substrate, each of the electrical leads configured to transmit electrical current orthogonal to the second magnetic field produced by the ferromagnet, wherein in response to the second magnetic field, the positive and negative electrical couplings are configured to generate a flow of electrons along the plurality of electrical leads in response to a spin current of electrons within the polymer layer.
29. The solar energy conversion system of Example 28, further comprising an electromagnetic receiver configured to generate electromagnetic waves configured to resonate with the magnetic field of the permanent magnet to direct photons toward the permanent magnet to increase the flux of photons that are attracted toward the base of the permanent magnet.
30. The solar energy conversion system of Example 29, further comprising an antenna disposed along at least a portion of the permanent magnet, the antenna configured to emit the electromagnetic waves generated by the electromagnetic receiver.
31. The solar energy conversion system of any of Examples 28-30, further comprising any of the features recited in Examples 1-27.
32. A solar energy conversion system configured to increase a flux of photons from solar radiation, the system comprising:
   a solar panel comprising a semiconductor substrate extending generally along a plane and configured to convert the flux of photons from solar radiation to electrical power, the solar panel comprising a frame extending about a periphery of the semiconductor substrate;
   a permanent magnet comprising a body having a helical shape extending along an axis perpendicular to the plane, the body comprising a base and a free end, the base connected to the solar panel, the body having a decreasing diameter along the axis toward the free end, the helical shape of the body having a largest diameter proximate the base relative to a diameter of the body proximate the free end, the body having a decreasing thickness along the axis toward the free end, the body having a greatest thickness proximate the base relative to a thickness of the body proximate the free end, wherein a magnitude of a magnetic field of the permanent magnet is greatest proximate the base relative to a magnitude of the magnetic field of the permanent magnet proximate the free end, wherein the magnetic field attracts photons toward the base of the permanent magnet;
   an electromagnetic receiver configured to generate electromagnetic waves configured to resonate with the magnetic field of the permanent magnet to direct photons toward the permanent magnet to increase the flux of photons that are attracted toward the base of the permanent magnet; and
   an antenna disposed along at least a portion of the permanent magnet, the antenna configured to emit the electromagnetic waves generated by the electromagnetic receiver.
33. The solar energy conversion system of Example 32, further comprising an inverse spin hall effect (ISHE) generator configured to modify a velocity of photons moving toward the base of the permanent magnet to direct the increased flux of photons toward the semiconductor substrate, the ISHE connected to and extending along the frame of the solar panel, the ISHE generator comprising:
   a positive electrical coupling;
   a negative electrical coupling;
   a polymer layer disposed axially above and between the positive and negative electrical couplings, the polymer layer comprising a dielectric; and
   a ferromagnet coupled axially above the polymer layer and configured to generate a second magnetic field, wherein the polymer separates the positive and negative couplings from each other and separates the ferromagnet from each of the positive and negative couplings, the dielectric configured to increase resistance of a flow of electricity between the ferromagnet and the positive or negative electrical couplings via the polymer, wherein in response to the second magnetic field applied to the polymer layer, the ferromagnet is configured to modify a velocity of photons to increase absorption of the photons by the semiconductor substrate.
34. The solar energy conversion system of Example 33, wherein the ISHE generator further comprises a plurality of electrical leads each coupled to corresponding of the positive and negative electrical couplings, each of the plurality of electrical leads disposed substantially parallel to the plane and to an edge of the semiconductor substrate, each of the electrical leads configured to transmit electrical current orthogonal to the second magnetic field produced by the ferromagnet, wherein in response to the second magnetic field, the positive and negative electrical couplings are configured to generate a flow of electrons along the plurality of electrical leads in response to a spin current of electrons within the polymer layer.
35. The solar energy conversion system of any of Examples 32-34, further comprising any of the features recited in Examples 1-27.
36. A solar energy conversion system configured to increase a flux of photons from solar radiation, the system comprising:
   a solar panel comprising a semiconductor substrate extending generally along a plane and configured to convert the flux of photons from solar radiation to electrical power; and
      a permanent magnet comprising a body having a helical shape extending along an axis perpendicular to the plane and configured to generate a magnetic field, the body comprising a base and a free end, the base connected to the solar panel, the body having a decreasing diameter along the axis toward the free end, the helical shape of the body having a largest diameter proximate the base relative to a diameter of the body proximate the free end, the body having a decreasing thickness along the axis toward the free end, the body having a greatest thickness proximate the base relative to a thickness of the body proximate the free end.
37. The solar energy conversion system of Example 36, wherein the solar panel comprises a frame extending about a periphery of the semiconductor substrate.
38. The solar energy conversion system of Example 37, further comprising an inverse spin hall effect (ISHE) generator configured to modify a velocity of photons moving toward the base of the permanent magnet to direct the increased flux of photons toward the semiconductor substrate, the ISHE connected to and extending along the frame of the solar panel, the ISHE generator comprising:
   a positive electrical coupling;
   a negative electrical coupling;
   a polymer layer disposed axially above and between the positive and negative electrical couplings, the polymer layer comprising a dielectric;
   a ferromagnet coupled axially above the polymer layer and configured to generate a second magnetic field, wherein the polymer separates the positive and negative couplings from each other and separates the ferromagnet from each of the positive and negative couplings, the dielectric configured to increase resistance of a flow of electricity between the ferromagnet and the positive or negative electrical couplings via the polymer, wherein in response to the second magnetic field applied to the polymer layer, the ferromagnet is configured to modify a velocity of photons to increase absorption of the photons by the semiconductor substrate; and
   a plurality of electrical leads each coupled to corresponding of the positive and negative electrical couplings, each of the plurality of electrical leads disposed substantially parallel to the plane and to an edge of the semiconductor substrate, each of the electrical leads configured to transmit electrical current orthogonal to the second magnetic field produced by the ferromagnet, wherein in response to the second magnetic field, the positive and negative electrical couplings are configured to generate a flow of electrons along the plurality of electrical leads in response to a spin current of electrons within the polymer layer.
39. The solar energy conversion system of any of Examples 36-38, further comprising any of the features recited in Examples 1-27.
40. An energy conversion system configured to increase a flux of photons from electromagnetic radiation, the system comprising:
   a panel comprising a semiconductor substrate extending generally along a plane and configured to convert the flux of photons from electromagnetic radiation to electrical power, the panel comprising a frame extending about a periphery of the semiconductor substrate; and
   an inverse spin hall effect (ISHE) generator configured to modify a velocity of photons moving toward the panel to direct the increased flux of photons toward the semiconductor substrate, the ISHE connected to and extending along the frame of the panel, the ISHE generator comprising:
      a polymer layer;
      a ferromagnet coupled axially above the polymer layer and configured to generate a second magnetic field; and
      a plurality of electrical leads.
41. The energy conversion system of Example 40, further comprising a positive electrical coupling and a negative electrical coupling.
42. The energy conversion system of Example 41, wherein the polymer layer is disposed axially above and between the positive and negative electrical couplings.
43. The energy conversion system of Example 42, wherein the polymer separates the positive and negative couplings from each other and separates the ferromagnet from each of the positive and negative couplings.
44. The energy conversion system of Example 43, wherein each of the each plurality of electrical leads is coupled to corresponding of the positive and negative electrical couplings.
45. The energy conversion system of any of Examples 40-44, wherein the polymer layer comprising a dielectric.
46. The energy conversion system of Example 45, wherein the dielectric comprises a ceramic.
47. The energy conversion system of any of Examples 45-46, wherein the dielectric is configured to increase resistance of a flow of electricity between the ferromagnet and the positive or negative electrical couplings via the polymer.
48. The energy conversion system of any of Examples 40-47, wherein in response to the second magnetic field applied to the polymer layer, the ferromagnet is configured to modify a velocity of photons to increase absorption of the photons by the semiconductor substrate.
49. The energy conversion system of any of Examples 40-48, wherein each of the plurality of electrical leads is disposed substantially parallel to the plane and to an edge of the semiconductor substrate.
50. The energy conversion system of any of Examples 40-49, wherein each of the electrical leads is configured to transmit electrical current orthogonal to the second magnetic field produced by the ferromagnet.
51. The energy conversion system of any of Examples 40-50, wherein in response to the second magnetic field, the positive and negative electrical couplings are configured to generate a flow of electrons along the plurality of electrical leads in response to a spin current of electrons within the polymer layer.
52. The energy conversion system of any of Examples 40-51, further comprising any of the features recited in Examples 1-27.
53. A vehicle aerodynamic system configured to reduce fluid drag on a vehicle, the system comprising:
   a plurality of piezoceramic transducers configured to be positioned proximate to an exterior surface of the vehicle, the plurality of piezoceramic transducers each configured convert electric current from a battery of the vehicle to ultrasound waves and to emit the ultrasound waves toward ambient airflow proximate the exterior surface of the vehicle that exerts pressure on the exterior of the vehicle as the vehicle moves through ambient air to convert turbulent flow of the ambient airflow to laminar flow proximate the exterior of the vehicle to reduce pressure exerted by the ambient airflow on the exterior of the vehicle moving through ambient air, thereby reducing airflow drag on the vehicle;
   a plurality of pressure sensors configured to be positioned proximate to the exterior surface of the vehicle, the plurality of pressure sensors each configured to detect a pressure of the ambient airflow at a location of a corresponding piezoceramic transducer and to generate a pressure signal corresponding to the pressure at the location;
   a controller configured to receive the pressure signal from each of the plurality of pressure sensors and to determine a target ultrasound wave based on the pressure signal and to cause the corresponding piezoceramic transducer to emit the target ultrasound wave to convert turbulent flow of the ambient airflow to laminar flow of the ambient airflow proximate the exterior of the vehicle to reduce airflow drag on the vehicle;
   an inverse spin hall effect (ISHE) generator configured to be positioned at least partially about an electric motor or at least partially about a shell or a chassis of the vehicle, the ISHE generator configured to generate electric power from an electromagnetic field generated by the electric motor of the vehicle, the ISHE generator comprising:
      a positive electrical coupling;
      a negative electrical coupling;
      a ferromagnet configured to generate a second electromagnetic field to modify the electromagnetic field generated by the electric motor;
      a polymer layer disposed on and between each of the positive and negative electrical couplings, wherein the polymer layer separates the positive and negative couplings from each other and separates the ferromagnet from each of the positive and negative couplings, the polymer layer comprising a dielectric, the dielectric increasing resistance of a flow of electricity between the ferromagnet and the positive or negative electrical couplings via the polymer layer; and
      a plurality of electrical leads each coupled to corresponding of the positive and negative electrical couplings, each of the plurality of electrical leads disposed about the electric motor of the vehicle, each of the electrical leads configured to interact with the polymer layer and with the electromagnetic field generated by the electric motor and modified by the ferromagnet, wherein in response to an interaction of the plurality of electrical leads with the polymer layer and with the modified electromagnetic field, the positive and negative electrical couplings are configured to generate a flow of electrons along the plurality of electrical leads in response to a spin state of electrons within the polymer layer to at least one of power the plurality of piezoceramic transducers or charge the battery of the vehicle via the flow of electrons;
   an antenna configured to be positioned at least partially about the electric motor of the vehicle, the antenna configured to detect an electromagnetic field emitted by the electric motor and to generate a field signal indicative of the electromagnetic field;
   an electromagnetic receiver configured to receive the field signal from the antenna and to determine, based on the field signal, resonance electromagnetic waves that resonate with the electromagnetic field emitted by the electric motor, the electromagnetic receiver configured to cause the antenna to emit the resonance electromagnetic waves toward the shell or the chassis of the vehicle, wherein the electromagnetic field emitted by the electric motor corresponds to a speed of operation of the electric motor; and
   a plurality of dielectric rods each configured to connect to the shell or the chassis of the vehicle and to the electric motor, each of the plurality of dielectric rods configured to receive the electromagnetic field from the electric motor and to transmit the electromagnetic field to the shell or the chassis of the vehicle,
   wherein the electromagnetic field at the shell or the chassis of the vehicle resonates with the resonance electromagnetic waves at the shell or the chassis of the vehicle to power the plurality of piezoceramic transducers via the resonance in the shell or the chassis of the vehicle to reduce power output from the battery for causing emission of the ultrasound waves by the plurality of piezoceramic transducers, wherein reduction in power output from the battery increases as the speed of operation of the electric motor increases, wherein increasing speed of operation of the electric motor increases at least one of amplitude or frequency of the electromagnetic field emitted by the electric motor that increases resonance with corresponding electromagnetic waves in the shell or the chassis of the vehicle.
54. The vehicle aerodynamic system of Example 53, wherein resonance of the electromagnetic field and the resonance electromagnetic waves in the shell or the chassis of the vehicle fully powers the plurality of piezoceramic transducers without power output from the battery.
55. The vehicle aerodynamic system of any of Examples 53-54, further comprising an inverse hall effect (IHE) generator configured to be positioned at least partially about the electric motor or at least partially about the shell or the chassis of the vehicle and to generate electric power from the electromagnetic field generated by the electric motor of the vehicle, the IHE generator comprising:
   an IHE battery comprising a positive and a negative terminal; and
   a second plurality of electrical leads each coupled to corresponding terminals of the IHE battery, each of the second plurality of electrical leads disposed about the electric motor of the vehicle, each of the second plurality of electrical leads configured to interact with the electromagnetic field generated by the electric motor, wherein in response to an interaction of the second plurality of electrical leads with the electromagnetic field, the second plurality of electrical leads are configured to at least one of power the plurality of piezoceramic transducers or generate a voltage between the positive and negative terminals of the THE battery.
56. The vehicle aerodynamic system of Example 55, wherein the IHE generator is configured to generate alternating current.
57. The vehicle aerodynamic system of any of Examples 55-56, wherein the battery of the vehicle comprises the IHE battery.
58. The vehicle aerodynamic system of any of Examples 53-57, wherein the electromagnetic receiver is configured to determine, based on the pressure signal, a resonance adjustment factor and transmit the resonance adjustment factor to the antenna for generating the resonance electromagnetic waves, wherein the resonance adjustment factor is higher in response to a higher speed of operation of the electric motor and is lower in response to a lower speed of operation of the electric motor.
59. The vehicle aerodynamic system of any of Examples 53-58, further comprising a microwave generator connected to each of the piezoceramic transducers and configured to emit microwaves.
60. The vehicle aerodynamic system of Example 59, wherein the plurality of piezoceramic transducers are each configured to receive the microwaves and convert the microwaves to ultrasound waves and emit the ultrasound waves toward the fluid.
61. The vehicle aerodynamic system of any of Examples 59-60, wherein resonance of the electromagnetic field and the resonance electromagnetic waves in the shell or the chassis of the vehicle fully powers the plurality of piezoceramic transducers without power output from the microwave generator.
62. The vehicle aerodynamic system of any of Examples 53-61, wherein the positive and negative electrical couplings are configured to generate the flow of electrons along the plurality of electrical leads further in response to a spin state of electrons within the polymer layer.
63. The vehicle aerodynamic system of any of Examples 53-62, further comprising a battery connected to the ISHE generator and configured to store the electrical power generated by the ISHE generator.
64. The vehicle aerodynamic system of any of Examples 53-63, wherein the ISHE is configured to generate direct current to charge the battery.
65. The vehicle aerodynamic system of any of Examples 53-64, wherein the plurality of piezoceramic transducers comprises an upper plurality of piezoceramic transducers and a lower plurality of piezoceramic transducers, each of the upper plurality of piezoceramic transducers configured to be positioned proximate to an upper surface of the vehicle with lower pressure from ambient airflow with the vehicle moving through ambient air and each of the lower plurality of piezoceramic transducers configured to be positioned proximate to a lower surface of the vehicle with higher pressure relative to the lower pressure from ambient airflow with the vehicle moving through ambient air.
66. The vehicle aerodynamic system of Example 65, wherein the controller is configured to receive first pressure signals from each of an upper plurality of pressure sensors and to receive second pressure signals from each of a lower plurality of pressure sensors, wherein the controller is configured to determine first target ultrasound waves based on the first pressure signals for piezoceramic transducers corresponding to each of the upper plurality of piezoceramic transducers, wherein the controller is configured to determine second target ultrasound waves based on the second pressure signals for the piezoceramic transducers corresponding to each of the lower plurality of piezoceramic transducers, wherein the target ultrasound waves comprise the first and second target ultrasound waves, the controller configured to cause the plurality of piezoceramic transducers to emit the first and second target ultrasound waves, wherein the first target ultrasound waves have at least one of a higher amplitude or frequency than the second target ultrasound waves.
67. The vehicle aerodynamic system of Example 66, wherein each of the target ultrasound waves has a higher amplitude or frequency in response to the speed of operation of the electric motor being higher or in response to the pressure of the ambient airflow at the location of the corresponding piezoceramic transducer being higher.
68. The vehicle aerodynamic system of any of Examples 53-67, wherein the ISHE generator is configured to be positioned at least partially on the electric motor.
69. The vehicle aerodynamic system of any of Examples 53-68, wherein the ISHE generator is configured to be positioned at least partially on the shell of the vehicle.
70. The vehicle aerodynamic system of any of Examples 53-69, wherein the ISHE generator is configured to be positioned at least partially about the electric motor.
71. The vehicle aerodynamic system of any of Examples 53-70, wherein the ISHE generator is configured to be positioned at least partially about the shell of the vehicle.
72. The vehicle aerodynamic system of any of Examples 53-71, wherein the ISHE generator comprises a plurality of ISHE generators each positioned proximate an edge of the electric motor or proximate an edge of a casing about the electric motor.
73. The vehicle aerodynamic system of Example 72, wherein the antenna is configured to be positioned between at least two of the plurality of ISHE generators.
74. The vehicle aerodynamic system of any of Examples 53-73, wherein the ISHE generator is positioned proximate an edge of a casing about the electric motor, wherein the casing is electrically conductive.
75. The vehicle aerodynamic system of Example 74, wherein the antenna is configured to be connected to the electrically conductive casing.
76. The vehicle aerodynamic system of any of Examples 53-75, wherein the antenna is configured to be positioned toward a center of the electric motor.
77. The vehicle aerodynamic system of any of Examples 53-76, wherein the electromagnetic receiver is configured to receive the field signal from a second antenna, wherein the electromagnetic receiver is configured to cause the second antenna to emit the resonance electromagnetic waves toward the shell or the chassis of the vehicle.
78. The vehicle aerodynamic system of Example 77, wherein the second antenna is a radio antenna of the vehicle.
79. The vehicle aerodynamic system of any of Examples 53-78, wherein the electromagnetic receiver is configured to cause a second antenna to emit the resonance electromagnetic waves toward the shell or the chassis of the vehicle.
80. The vehicle aerodynamic system of any of Examples 53-79, wherein the resonance electromagnetic waves comprise radio waves.
81. The vehicle aerodynamic system of any of Examples 53-80 wherein the resonance electromagnetic waves comprise microwaves.
82. The vehicle aerodynamic system of any of Examples 53-81, wherein, in response to the electric motor operating at a higher speed, thereby causing a higher frequency of the electromagnetic field, the resonance electromagnetic waves comprise a higher frequency.
83. The vehicle aerodynamic system of any of Examples 53-82, wherein the flow of electrons along the plurality of electrical leads charges the battery of the vehicle.
84. The vehicle aerodynamic system of any of Examples 53-83, further comprising a direct current regulator connected to the ISHE generator, the direct current regulator configured to charge the battery from power generated by the ISHE generator.
85. The vehicle aerodynamic system of any of Examples 53-84, wherein the target ultrasound waves modulate an amplitude or a frequency of the target ultrasound waves in response to a different frequency or amplitude of the electromagnetic field.
86. The vehicle aerodynamic system of Example 85, wherein the target ultrasound waves have a higher amplitude or frequency in response to a higher frequency or amplitude of the electromagnetic field in response to the electric motor operating at a higher speed.
87. The vehicle aerodynamic system of any of Examples 53-86, wherein the controller is configured to receive the field signal indicative of the electromagnetic field from the antenna and, in response to a higher amplitude or frequency of the electromagnetic field emitted by the electric motor, to determine target ultrasound waves having a higher amplitude or frequency corresponding to the higher amplitude or frequency of the electromagnetic field.
88. The vehicle aerodynamic system of any of Examples 53-87, wherein the resonance transfers at least 1 Watt of power.
89. The vehicle aerodynamic system of any of Examples 53-88, wherein the reduction in power output from the battery comprises at least 1 Watt per piezoceramic transducer.
90. The vehicle aerodynamic system of any of Examples 53-89, wherein the resonance has a frequency of between 1 kHz and 100 kHz.
91. An fluid dynamic system configured to reduce fluid drag on a moving object, the system comprising:
   a plurality of piezoceramic transducers configured to be positioned proximate to an exterior surface of the object, the plurality of piezoceramic transducers each configured convert electric current from a battery of the object to ultrasound waves and to emit the ultrasound waves toward fluid proximate the exterior surface of the object that exerts pressure on the exterior of the object as the object moves through the fluid to convert turbulent flow of the fluid to laminar flow proximate the exterior of the object to reduce pressure exerted by the fluid on the exterior of the object moving through the fluid, thereby reducing fluid drag on the object;
   a plurality of pressure sensors configured to be positioned proximate to the exterior surface of the object, the plurality of pressure sensors each configured to detect a pressure of the fluid at a location of a corresponding piezoceramic transducer and to generate a pressure signal corresponding to the pressure at the location;
   a controller configured to receive the pressure signal from each of the plurality of pressure sensors and to determine a target ultrasound wave based on the pressure signal for the corresponding piezoceramic transducer to emit the target ultrasound wave to convert turbulent flow of the fluid to laminar flow of the fluid proximate the exterior of the object to reduce fluid drag on the object;
   an inverse spin hall effect (ISHE) generator configured to be positioned at least partially about an electric motor or at least partially about a shell or a chassis of the object, the ISHE generator configured to generate electric power from an electromagnetic field generated by the electric motor of the object, the ISHE generator comprising:
      a positive electrical coupling;
      a negative electrical coupling;
      a ferromagnet configured to generate a second electromagnetic field to modify the electromagnetic field generated by the electric motor;
      a polymer layer disposed on and between each of the positive and negative electrical couplings, wherein the polymer layer separates the positive and negative couplings from each other and separates the ferromagnet from each of the positive and negative couplings, the polymer layer comprising a dielectric, the dielectric increasing resistance of a flow of electricity between the ferromagnet and the positive or negative electrical couplings via the polymer layer; and
      a plurality of electrical leads each coupled to corresponding of the positive and negative electrical couplings, each of the plurality of electrical leads disposed about the electric motor of the object, each of the electrical leads configured to interact with the polymer layer and with the electromagnetic field generated by the electric motor and modified by the ferromagnet, wherein in response to an interaction of the plurality of electrical leads with the polymer layer and with the modified electromagnetic field, the positive and negative electrical couplings are configured to generate a flow of electrons along the plurality of electrical leads in response to a spin state of electrons within the polymer layer to at least one of power the plurality of piezoceramic transducers or charge the battery of the object via the flow of electrons;
   an antenna configured to be positioned at least partially about the electric motor of the object, the antenna configured to detect an electromagnetic field emitted by the electric motor and to generate a field signal indicative of the electromagnetic field;
   an electromagnetic receiver configured to receive the field signal from the antenna and to determine, based on the field signal, resonance electromagnetic waves that resonate with the electromagnetic field emitted by the electric motor, the electromagnetic receiver configured to cause the antenna to emit the resonance electromagnetic waves toward the shell or the chassis of the object, wherein the electromagnetic field emitted by the electric motor is based on a speed of operation of the electric motor; and
   a plurality of dielectric rods each configured to connect to the shell or the chassis of the object and to the electric motor, each of the plurality of dielectric rods configured to receive the electromagnetic field from the electric motor and to transmit the electromagnetic field to the shell or the chassis of the object,
   wherein the electromagnetic field at the shell or the chassis of the object resonates with the resonance electromagnetic waves at the shell or the chassis of the object to power the plurality of piezoceramic transducers via the resonance in the shell or the chassis of the object to reduce power output from the battery for causing emission of the ultrasound waves by the plurality of piezoceramic transducers.
92. The fluid dynamic system of Example 91, wherein reduction in power output from the battery increases as the speed of operation of the electric motor increases.
93. The fluid dynamic system of Example 92, wherein increasing speed of operation of the electric motor increases at least one of amplitude or frequency of the electromagnetic field emitted by the electric motor that increases resonance with corresponding resonance electromagnetic waves in the shell or the chassis of the object.
94. The fluid dynamic system of any of Examples 91-93, wherein the electromagnetic field emitted by the electric motor corresponds to the speed of operation of the electric motor.
95. The fluid dynamic system of any of Examples 91-94, wherein the object comprises a vehicle.
96. The fluid dynamic system of any of Examples 91-95, wherein the fluid comprises air.
97. The fluid dynamic system of any of Examples 91-96, further including any of the features of Examples 53-90.
98. A fluid dynamic system configured to reduce fluid drag on a moving object, the system comprising:
   a plurality of piezoceramic transducers configured to be positioned proximate to an exterior surface of the object, the plurality of piezoceramic transducers each configured convert electric current from a battery of the object to ultrasound waves and to emit the ultrasound waves toward fluid proximate the exterior surface of the object that exerts pressure on the exterior of the object as the object moves through the fluid to convert turbulent flow of the fluid to laminar flow proximate the exterior of the object to reduce pressure exerted by the fluid on the exterior of the object moving through the fluid, thereby reducing fluid drag on the object;
   a plurality of pressure sensors configured to be positioned proximate to the exterior surface of the object, the plurality of pressure sensors each configured to detect a pressure of the fluid at a location of a corresponding piezoceramic transducer and to generate a pressure signal corresponding to the pressure at the location;
   a controller configured to receive the pressure signal from each of the plurality of pressure sensors and to determine a target ultrasound wave based on the pressure signal for the corresponding piezoceramic transducer to emit the target ultrasound wave to convert turbulent flow of the fluid to laminar flow of the fluid proximate the exterior of the object to reduce fluid drag on the object; and
   an inverse spin hall effect (ISHE) generator configured to be positioned at least partially about an electric motor or at least partially about a shell or a chassis of the object, the ISHE generator configured to generate electric power from an electromagnetic field generated by the electric motor of the object, the ISHE generator comprising:
      a positive electrical coupling;
      a negative electrical coupling;
      a ferromagnet configured to generate a second electromagnetic field to modify the electromagnetic field generated by the electric motor;
      a polymer layer disposed on and between each of the positive and negative electrical couplings, wherein the polymer layer separates the positive and negative couplings from each other and separates the ferromagnet from each of the positive and negative couplings, the polymer layer comprising a dielectric, the dielectric increasing resistance of a flow of electricity between the ferromagnet and the positive or negative electrical couplings via the polymer layer; and
      a plurality of electrical leads each coupled to corresponding of the positive and negative electrical couplings, each of the plurality of electrical leads disposed about the electric motor of the object, each of the electrical leads configured to interact with the polymer layer and with the electromagnetic field generated by the electric motor and modified by the ferromagnet, wherein in response to an interaction of the plurality of electrical leads with the polymer layer and with the modified electromagnetic field, the positive and negative electrical couplings are configured to generate a flow of electrons along the plurality of electrical leads in response to a spin state of electrons within the polymer layer to at least one of power the plurality of piezoceramic transducers or charge the battery of the object via the flow of electrons.
99. The fluid dynamic system of Example 98, further comprising an antenna configured to be positioned at least partially about the electric motor of the object, the antenna configured to detect an electromagnetic field emitted by the electric motor and to generate a field signal indicative of the electromagnetic field.
100. The fluid dynamic system of Example 99, further comprising an electromagnetic receiver configured to receive the field signal from the antenna and to determine, based on the field signal, resonance electromagnetic waves that resonate with the electromagnetic field emitted by the electric motor, the electromagnetic receiver configured to cause the antenna to emit the resonance electromagnetic waves toward the shell or the chassis of the object, wherein the electromagnetic field emitted by the electric motor is based on a speed of operation of the electric motor.
101. The fluid dynamic system of Example 100, further comprising a plurality of dielectric rods each configured to connect to the shell or the chassis of the object and to the electric motor, each of the plurality of dielectric rods configured to receive the electromagnetic field from the electric motor and to transmit the electromagnetic field to the shell or the chassis of the object.
102. The fluid dynamic system of Example 101, wherein the electromagnetic field at the shell or the chassis of the object resonates with the resonance electromagnetic waves at the shell or the chassis of the object to power the plurality of piezoceramic transducers via the resonance in the shell or the chassis of the object to reduce power output from the battery for causing emission of the ultrasound waves by the plurality of piezoceramic transducers.
103. The fluid dynamic system of Example 102, wherein reduction in power output from the battery increases as the speed of operation of the electric motor increases.
104. The fluid dynamic system of Example 103, wherein increasing speed of operation of the electric motor increases at least one of amplitude or frequency of the electromagnetic field emitted by the electric motor that increases resonance with corresponding resonance electromagnetic waves in the shell or the chassis of the object.
105. The fluid dynamic system of any of Examples 98-104, further including any of the features of Examples 53-90.
106. A fluid dynamic system configured to reduce fluid drag on a moving object, the system comprising:
   a plurality of piezoceramic transducers configured to be positioned proximate to an exterior surface of the object, the plurality of piezoceramic transducers each configured convert electric current from a battery of the object to ultrasound waves and to emit the ultrasound waves toward fluid proximate the exterior surface of the object that exerts pressure on the exterior of the object as the object moves through the fluid to convert turbulent flow of the fluid to laminar flow proximate the exterior of the object to reduce pressure exerted by the fluid on the exterior of the object moving through the fluid, thereby reducing fluid drag on the object;
   a plurality of pressure sensors configured to be positioned proximate to the exterior surface of the object, the plurality of pressure sensors each configured to detect a pressure of the fluid at a location of a corresponding piezoceramic transducer and to generate a pressure signal corresponding to the pressure at the location;
   a controller configured to receive the pressure signal from each of the plurality of pressure sensors and to determine a target ultrasound wave based on the pressure signal for the corresponding piezoceramic transducer to emit the target ultrasound wave to convert turbulent flow of the fluid to laminar flow of the fluid proximate the exterior of the object to reduce fluid drag on the object;
   an antenna configured to be positioned at least partially about an electric motor of the object, the antenna configured to detect an electromagnetic field emitted by the electric motor and to generate a field signal indicative of the electromagnetic field;
   an electromagnetic receiver configured to receive the field signal from the antenna and to determine, based on the field signal, resonance electromagnetic waves that resonate with the electromagnetic field emitted by the electric motor, the electromagnetic receiver configured to cause the antenna to emit the resonance electromagnetic waves toward a shell or a chassis of the object, wherein the electromagnetic field emitted by the electric motor is based on a speed of operation of the electric motor; and
   a plurality of dielectric rods each configured to connect to the shell or the chassis of the object and to the electric motor, each of the plurality of dielectric rods configured to receive the electromagnetic field from the electric motor and to transmit the electromagnetic field to the shell or the chassis of the object,
   wherein the electromagnetic field at the shell or the chassis of the object resonates with the resonance electromagnetic waves at the shell or the chassis of the object to power the plurality of piezoceramic transducers via the resonance in the shell or the chassis of the object to reduce power output from the battery for causing emission of the ultrasound waves by the plurality of piezoceramic transducers.
107. The fluid dynamic system of Example 106, wherein reduction in power output from a battery of the object increases as the speed of operation of the electric motor of the object increases.
108. The fluid dynamic system of Example 107, wherein increasing speed of operation of the electric motor increases at least one of amplitude or frequency of the electromagnetic field emitted by the electric motor that increases resonance with corresponding resonance electromagnetic waves in the shell or the chassis of the object.
109. The fluid dynamic system of any of Examples 106-108, further comprising an inverse spin hall effect (ISHE) generator configured to be positioned at least partially about an electric motor or at least partially about a shell or a chassis of the object, the ISHE generator configured to generate electric power from an electromagnetic field generated by the electric motor of the object, the ISHE generator comprising a positive electrical coupling and a negative electrical coupling.
110. The fluid dynamic system of Example 109, wherein the ISHE generator further comprises a ferromagnet configured to generate a second electromagnetic field to modify the electromagnetic field generated by the electric motor.
111. The fluid dynamic system of Example 110, wherein the ISHE generator further comprises a polymer layer disposed on and between each of the positive and negative electrical couplings, wherein the polymer layer separates the positive and negative couplings from each other and separates the ferromagnet from each of the positive and negative couplings.
112. The fluid dynamic system of Example 111, wherein the polymer layer comprises a dielectric, the dielectric increasing resistance of a flow of electricity between the ferromagnet and the positive or negative electrical couplings via the polymer layer.
113. The fluid dynamic system of any of Examples 111-112, wherein the ISHE generator further comprises a plurality of electrical leads each coupled to corresponding of the positive and negative electrical couplings, each of the plurality of electrical leads disposed about the electric motor of the object.
114. The fluid dynamic system of Example 113, wherein each of the electrical leads is configured to interact with the polymer layer and with the electromagnetic field generated by the electric motor and modified by the ferromagnet.
115. The fluid dynamic system of Example 114, wherein in response to an interaction of the plurality of electrical leads with the polymer layer and with the modified electromagnetic field, the positive and negative electrical couplings are configured to generate a flow of electrons along the plurality of electrical leads in response to a spin state of electrons within the polymer layer to at least one of power the plurality of piezoceramic transducers or charge the battery of the object via the flow of electrons.
116. The fluid dynamic system of any of Examples 106-115, further including any of the features of Examples 53-90.
117. A fluid dynamic system configured to reduce fluid drag on a moving object, the system comprising:
   a plurality of piezoceramic transducers configured to be positioned proximate to an exterior surface of the object, the plurality of piezoceramic transducers each configured convert electric current from a battery or an electromagnetic wave generator of the object to ultrasound waves and to emit the ultrasound waves toward fluid proximate the exterior surface of the object that exerts pressure on the exterior of the object as the object moves through the fluid to convert turbulent flow of the fluid to laminar flow proximate the exterior of the object to reduce pressure exerted by the fluid on the exterior of the object moving through the fluid, thereby reducing fluid drag on the object; and
   a controller configured to determine a target ultrasound wave for a corresponding piezoceramic transducer to emit the target ultrasound wave to convert turbulent flow of the fluid to laminar flow of the fluid proximate the exterior of the object to reduce fluid drag on the object.
118. The fluid dynamic system of Example 117, further comprising a plurality of pressure sensors configured to be positioned proximate to the exterior surface of the object, the plurality of pressure sensors each configured to detect a pressure of the fluid at a location of a corresponding piezoceramic transducer and to generate a pressure signal corresponding to the pressure at the location.
119. The fluid dynamic system of Example 118, wherein the controller is further configured to receive the pressure signal from each of the plurality of pressure sensors.
120. The fluid dynamic system of Example 119, wherein the controller is configured to determine the target ultrasound waves based on the pressure signal.
121. The fluid dynamic system of any of Examples 117-120, further comprising an inverse spin hall effect (ISHE) generator configured to be positioned at least partially about an electric motor or at least partially about a shell or a chassis of the object, the ISHE generator configured to generate electric power from an electromagnetic field generated by the electric motor of the object, the ISHE generator comprising:
   a positive electrical coupling;
   a negative electrical coupling;
   a ferromagnet configured to generate a second electromagnetic field to modify the electromagnetic field generated by the electric motor;
   a polymer layer disposed on and between each of the positive and negative electrical couplings, wherein the polymer layer separates the positive and negative couplings from each other and separates the ferromagnet from each of the positive and negative couplings, the polymer layer comprising a dielectric, the dielectric increasing resistance of a flow of electricity between the ferromagnet and the positive or negative electrical couplings via the polymer layer; and
   a plurality of electrical leads each coupled to corresponding of the positive and negative electrical couplings, each of the plurality of electrical leads disposed about the electric motor of the object, each of the electrical leads configured to interact with the polymer layer and with the electromagnetic field generated by the electric motor and modified by the ferromagnet, wherein in response to an interaction of the plurality of electrical leads with the polymer layer and with the modified electromagnetic field, the positive and negative electrical couplings are configured to generate a flow of electrons along the plurality of electrical leads in response to a spin state of electrons within the polymer layer to at least one of power the plurality of piezoceramic transducers or charge the battery of the object via the flow of electrons.
122. The fluid dynamic system of any of Examples 117-121, further comprising an antenna configured to be positioned at least partially about an electric motor of the object, the antenna configured to detect an electromagnetic field emitted by the electric motor and to generate a field signal indicative of the electromagnetic field.
123. The fluid dynamic system of Example 122, further comprising an electromagnetic receiver configured to receive the field signal from the antenna and to determine, based on the field signal, resonance electromagnetic waves that resonate with the electromagnetic field emitted by the electric motor, the electromagnetic receiver configured to cause the antenna to emit the resonance electromagnetic waves toward a shell or a chassis of the object, wherein the electromagnetic field emitted by the electric motor is based on a speed of operation of the electric motor.
124. The fluid dynamic system of Example 123, further comprising a plurality of dielectric rods each configured to connect to the shell or the chassis of the object and to the electric motor, each of the plurality of dielectric rods configured to receive the electromagnetic field from the electric motor and to transmit the electromagnetic field to the shell or the chassis of the object.
125. The fluid dynamic system of Example 124, wherein the electromagnetic field at the shell or the chassis of the object resonates with the resonance electromagnetic waves at the shell or the chassis of the object to power the plurality of piezoceramic transducers via the resonance in the shell or the chassis of the object to reduce power output from the battery for causing emission of the ultrasound waves by the plurality of piezoceramic transducers.
126. The fluid dynamic system of any of Examples 117-125, further including any of the features of Examples 53-90.
127. An energy conversion system configured to generate electrical power from a moving object, the system comprising:
   an inverse spin hall effect (ISHE) generator configured to be positioned at least partially about an electric motor or at least partially about a shell or a chassis of the object, the ISHE generator configured to generate electric power from an electromagnetic field generated by the electric motor of the object, the ISHE generator comprising:
      a positive electrical coupling;
      a negative electrical coupling;
      a polymer layer disposed on and between each of the positive and negative electrical couplings, wherein the polymer layer separates the positive and negative couplings from each other; and
      a plurality of electrical leads each coupled to corresponding of the positive and negative electrical couplings, each of the plurality of electrical leads disposed about the electric motor of the object, each of the electrical leads configured to interact with the polymer layer and with the electromagnetic field generated by the electric motor, wherein in response to an interaction of the plurality of electrical leads with the polymer layer and with the electromagnetic field, the positive and negative electrical couplings are configured to generate a flow of electrons along the plurality of electrical leads.
128. The energy conversion system of Example 127, further comprising a ferromagnet configured to generate a second electromagnetic field to modify the electromagnetic field generated by the electric motor.
129. The energy conversion system of Example 128, wherein the polymer layer is further configured to separate the ferromagnet from each of the positive and negative couplings.
130. The energy conversion system of Example 129, wherein the polymer layer comprises a dielectric, the dielectric increasing resistance of a flow of electricity between the ferromagnet and the positive or negative electrical couplings via the polymer layer.
131. The energy conversion system of Example 130, wherein the plurality of electrical leads are configured to generate the flow of electrons in response to a spin state of electrons within the polymer layer to at least one of power a plurality of piezoceramic transducers or charge a battery of the object via the flow of electrons.
132. The energy conversion system of any of Examples 127-131, further comprising a plurality of piezoceramic transducers configured to be positioned proximate to an exterior surface of the object, the plurality of piezoceramic transducers each configured convert electric current from a battery of the object to ultrasound waves and to emit the ultrasound waves toward fluid proximate the exterior surface of the object that exerts pressure on the exterior of the object as the object moves through the fluid to convert turbulent flow of the fluid to laminar flow proximate the exterior of the object to reduce pressure exerted by the fluid on the exterior of the object moving through the fluid, thereby reducing fluid drag on the object.
133. The energy conversion system of any of Examples 127-132, further comprising a plurality of pressure sensors configured to be positioned proximate to an exterior surface of the object, the plurality of pressure sensors each configured to detect a pressure of an fluid at a location of a corresponding piezoceramic transducer and to generate a pressure signal corresponding to the pressure at the location.
134. The energy conversion system of Example 133, further comprising a controller configured to receive the pressure signal from each of the plurality of pressure sensors and to determine a target ultrasound wave based on the pressure signal for the corresponding piezoceramic transducer to emit the target ultrasound wave to convert turbulent flow of the fluid to laminar flow of the fluid proximate the exterior of the object to reduce fluid drag on the object.
135. The energy conversion system of Example 134, further comprising an antenna configured to be positioned at least partially about the electric motor of the object, the antenna configured to detect an electromagnetic field emitted by the electric motor and to generate a field signal indicative of the electromagnetic field.
136. The energy conversion system of Example 135, further comprising an electromagnetic receiver configured to receive the field signal from the antenna and to determine, based on the field signal, resonance electromagnetic waves that resonate with the electromagnetic field emitted by the electric motor, the electromagnetic receiver configured to cause the antenna to emit the resonance electromagnetic waves toward the shell or the chassis of the object, wherein the electromagnetic field emitted by the electric motor is based on a speed of operation of the electric motor.
137. The energy conversion system of Example 136, further comprising a plurality of dielectric rods each configured to connect to the shell or the chassis of the object and to the electric motor, each of the plurality of dielectric rods configured to receive the electromagnetic field from the electric motor and to transmit the electromagnetic field to the shell or the chassis of the object.
138. The energy conversion system of Example 137, wherein the electromagnetic field at the shell or the chassis of the object resonates with the resonance electromagnetic waves at the shell or the chassis of the object to power the plurality of piezoceramic transducers via the resonance in the shell or the chassis of the object to reduce power output from a battery for causing emission of the ultrasound waves by the plurality of piezoceramic transducers.
139. The energy conversion system of any of Examples 127-138, further including any of the features of Examples 53-90.
140. An energy conversion system configured to generate electrical power from a moving object, the system comprising:
   an inverse hall effect (IHE) generator configured to be positioned at least partially about an electric motor of the object or at least partially about a shell an object and to generate electric power from an electromagnetic field generated by the electric motor of the object, the IHE generator comprising:
      an IHE battery comprising a positive and a negative terminal; and
      a plurality of electrical leads each coupled to corresponding terminals of the THE battery, each of the plurality of electrical leads disposed about the electric motor of the object, each of the plurality of electrical leads configured to interact with the electromagnetic field generated by the electric motor, wherein in response to an interaction of the plurality of electrical leads with the electromagnetic field, the plurality of electrical leads are configured to generate a voltage between the positive and negative terminals of the IHE battery.
141. The energy conversion system of Example 140, further including any of the features of Examples 53-90.
142. A fluid dynamic system configured to reduce fluid drag on a moving object, the system comprising:
   a plurality of piezoceramic transducers configured to be positioned proximate to an exterior surface of the object and to emit ultrasound waves toward fluid proximate the exterior surface of the object that exerts pressure on the exterior of the object as the object moves through the fluid to convert turbulent flow of the fluid to laminar flow proximate the exterior of the object to reduce pressure exerted by the fluid on the exterior of the object moving through the fluid, thereby reducing fluid drag on the object;
   an inverse spin hall effect (ISHE) generator configured to be positioned at least partially about an electric motor or at least partially about a shell or a chassis of the object, the ISHE generator configured to generate electric power from an electromagnetic field generated by the electric motor of the object, the ISHE generator comprising:
      a positive electrical coupling;
      a negative electrical coupling;
      a polymer layer disposed on and between each of the positive and negative electrical couplings, wherein the polymer layer separates the positive and negative couplings from each other; and
      a plurality of electrical leads each coupled to corresponding of the positive and negative electrical couplings, each of the plurality of electrical leads disposed about the electric motor of the object, each of the electrical leads configured to interact with the polymer layer and with the electromagnetic field generated by the electric motor, wherein in response to an interaction of the plurality of electrical leads with the polymer layer and with the electromagnetic field, the positive and negative electrical couplings are configured to generate a flow of electrons along the plurality of electrical leads in response to a spin state of electrons within the polymer layer to at least one of power the plurality of piezoceramic transducers or charge a battery of the object via the flow of electrons;
   an antenna configured to be positioned at least partially about the electric motor of the object, the antenna configured to detect an electromagnetic field emitted by the electric motor and to generate a field signal indicative of the electromagnetic field; and
   an electromagnetic receiver configured to receive the field signal from the antenna and to determine, based on the field signal, resonance electromagnetic waves that resonate with the electromagnetic field emitted by the electric motor, the electromagnetic receiver configured to cause the antenna to emit the resonance electromagnetic waves toward the shell or the chassis of the object, wherein the electromagnetic field emitted by the electric motor is based on a speed of operation of the electric motor.
143. The fluid dynamic system of Example 142, wherein each of the plurality of piezoceramic transducers is configured convert electric current from a battery or electromagnetic generator of the object to the ultrasound waves.
144. The fluid dynamic system of Example 143, further comprising a plurality of pressure sensors configured to be positioned proximate to the exterior surface of the object, the plurality of pressure sensors each configured to detect a pressure of the fluid at a location of a corresponding piezoceramic transducer and to generate a pressure signal corresponding to the pressure at the location.
145. The fluid dynamic system of Example 144, further comprising a controller configured to receive the pressure signal from each of the plurality of pressure sensors and to determine a target ultrasound wave based on the pressure signal for the corresponding piezoceramic transducer to emit the target ultrasound wave to convert turbulent flow of the fluid to laminar flow of the fluid proximate the exterior of the object to reduce fluid drag on the object.
146. The fluid dynamic system of any of Examples 142-145, wherein the ISHE generator further comprises a ferromagnet configured to generate a second electromagnetic field to modify the electromagnetic field generated by the electric motor.
147. The fluid dynamic system of Example 146, wherein the polymer layer separates the ferromagnet from each of the positive and negative couplings, the polymer layer comprising a dielectric, the dielectric increasing resistance of a flow of electricity between the ferromagnet and the positive or negative electrical couplings via the polymer layer.
148. The fluid dynamic system of any of Examples 142-147, further comprising a plurality of dielectric rods each configured to connect to the shell or the chassis of the object and to the electric motor, each of the plurality of dielectric rods configured to receive the electromagnetic field from the electric motor and to transmit the electromagnetic field to the shell or the chassis of the object.
149. The fluid dynamic system of any of Examples 142-148, wherein the electromagnetic field at the shell or the chassis of the object resonates with the resonance electromagnetic waves at the shell or the chassis of the object to power the plurality of piezoceramic transducers via the resonance in the shell or the chassis of the object to reduce power output from the battery for causing emission of the ultrasound waves by the plurality of piezoceramic transducers.
150. The fluid dynamic system of any of Examples 142-149, further including any of the features of Examples 53-90.

### Terminology

Moreover, while operations may be depicted in the drawings or described in the specification in a particular order, such operations need not be performed in the particular order shown or in sequential order, and all operations need not be performed, to achieve the desirable results. Other operations that are not depicted or described can be incorporated in the example methods and processes. For example, one or more additional operations can be performed before, after, simultaneously, or between any of the described operations. Further, the operations may be rearranged or reordered in other implementations. Also, the separation of various system components in the implementations described above should not be understood as requiring such separation in all implementations, and it should be understood that the described components and systems can generally be integrated together in a single product or packaged into multiple products. Additionally, other implementations are within the scope of this disclosure.

Conditional language, such as “can,” “could,” “might,” or “may,” unless specifically stated otherwise, or otherwise understood within the context as used, is generally intended to convey that certain configurations include or do not include, certain features, elements, and/or steps. Thus, such conditional language is not generally intended to imply that features, elements, and/or steps are in any way required for one or more configurations.

Conjunctive language, such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain configurations require the presence of at least one of X, at least one of Y, and at least one of Z.

Some configurations have been described in connection with the accompanying drawings. Components can be added, removed, and/or rearranged. Orientation references such as, for example, “top” and “bottom” are for ease of discussion and may be rearranged such that top features are proximate the bottom and bottom features are proximate the top. Further, the disclosure herein of any particular feature, aspect, method, property, characteristic, quality, attribute, element, or the like in connection with various configurations can be used in all other configurations set forth herein. Additionally, it will be recognized that any methods described herein may be practiced using any device suitable for performing the recited steps.

In summary, various configurations and examples of energy converting devices and methods have been disclosed. Although the systems and methods have been disclosed in the context of those configurations and examples, it will be understood by those skilled in the art that this disclosure extends beyond the specifically disclosed configurations to other alternative configurations and/or other uses of the configurations, as well as to certain modifications and equivalents thereof. This disclosure expressly contemplates that various features and aspects of the disclosed configurations can be combined with, or substituted for, one another. Accordingly, the scope of this disclosure should not be limited by the particular disclosed configurations described above, but should be determined only by a fair reading of the claims that follow.

1-90. (canceled)

91. A fluid dynamic system configured to reduce fluid drag on a moving object, the system comprising:
a plurality of piezoceramic transducers configured to be positioned proximate to an exterior surface of the object, the plurality of piezoceramic transducers each configured convert electric current from a battery of the object to ultrasound waves and to emit the ultrasound waves toward fluid proximate the exterior surface of the object that exerts pressure on the exterior of the object as the object moves through the fluid to convert turbulent flow of the fluid to laminar flow proximate the exterior of the object to reduce pressure exerted by the fluid on the exterior of the object moving through the fluid, thereby reducing fluid drag on the object;
a plurality of pressure sensors configured to be positioned proximate to the exterior surface of the object, the plurality of pressure sensors each configured to detect a pressure of the fluid at a location of a corresponding piezoceramic transducer and to generate a pressure signal corresponding to the pressure at the location;
a controller configured to receive the pressure signal from each of the plurality of pressure sensors and to determine a target ultrasound wave based on the pressure signal for the corresponding piezoceramic transducer to emit the target ultrasound wave to convert turbulent flow of the fluid to laminar flow of the fluid proximate the exterior of the object to reduce fluid drag on the object;
an inverse spin hall effect (ISHE) generator configured to be positioned at least partially about an electric motor or at least partially about a shell or a chassis of the object, the ISHE generator configured to generate electric power from an electromagnetic field generated by the electric motor of the object, the ISHE generator comprising:
a positive electrical coupling;
a negative electrical coupling;
a ferromagnet configured to generate a second electromagnetic field to modify the electromagnetic field generated by the electric motor;
a polymer layer disposed on and between each of the positive and negative electrical couplings, wherein the polymer layer separates the positive and negative couplings from each other and separates the ferromagnet from each of the positive and negative couplings, the polymer layer comprising a dielectric, the dielectric increasing resistance of a flow of electricity between the ferromagnet and the positive or negative electrical couplings via the polymer layer; and
a plurality of electrical leads each coupled to corresponding of the positive and negative electrical couplings, each of the plurality of electrical leads disposed about the electric motor of the object, each of the electrical leads configured to interact with the polymer layer and with the electromagnetic field generated by the electric motor and modified by the ferromagnet, wherein in response to an interaction of the plurality of electrical leads with the polymer layer and with the modified electromagnetic field, the positive and negative electrical couplings are configured to generate a flow of electrons along the plurality of electrical leads in response to a spin state of electrons within the polymer layer to at least one of power the plurality of piezoceramic transducers or charge the battery of the object via the flow of electrons;
an antenna configured to be positioned at least partially about the electric motor of the object, the antenna configured to detect an electromagnetic field emitted by the electric motor and to generate a field signal indicative of the electromagnetic field;
an electromagnetic receiver configured to receive the field signal from the antenna and to determine, based on the field signal, resonance electromagnetic waves that resonate with the electromagnetic field emitted by the electric motor, the electromagnetic receiver configured to cause the antenna to emit the resonance electromagnetic waves toward the shell or the chassis of the object, wherein the electromagnetic field emitted by the electric motor is based on a speed of operation of the electric motor; and
a plurality of dielectric rods each configured to connect to the shell or the chassis of the object and to the electric motor, each of the plurality of dielectric rods configured to receive the electromagnetic field from the electric motor and to transmit the electromagnetic field to the shell or the chassis of the object,
wherein the electromagnetic field at the shell or the chassis of the object resonates with the resonance electromagnetic waves at the shell or the chassis of the object to power the plurality of piezoceramic transducers via the resonance in the shell or the chassis of the object to reduce power output from the battery for causing emission of the ultrasound waves by the plurality of piezoceramic transducers.

92-94. (canceled)

95. The fluid dynamic system of claim 91, wherein the object comprises a vehicle.

96. (canceled)

97. (canceled)

98. A fluid dynamic system configured to reduce fluid drag on a moving object, the system comprising:
a plurality of piezoceramic transducers configured to be positioned proximate to an exterior surface of the object, the plurality of piezoceramic transducers each configured convert electric current from a battery of the object to ultrasound waves and to emit the ultrasound waves toward fluid proximate the exterior surface of the object that exerts pressure on the exterior of the object as the object moves through the fluid to convert turbulent flow of the fluid to laminar flow proximate the exterior of the object to reduce pressure exerted by the fluid on the exterior of the object moving through the fluid, thereby reducing fluid drag on the object;
a plurality of pressure sensors configured to be positioned proximate to the exterior surface of the object, the plurality of pressure sensors each configured to detect a pressure of the fluid at a location of a corresponding piezoceramic transducer and to generate a pressure signal corresponding to the pressure at the location;
a controller configured to receive the pressure signal from each of the plurality of pressure sensors and to determine a target ultrasound wave based on the pressure signal for the corresponding piezoceramic transducer to emit the target ultrasound wave to convert turbulent flow of the fluid to laminar flow of the fluid proximate the exterior of the object to reduce fluid drag on the object; and
an inverse spin hall effect (ISHE) generator configured to be positioned at least partially about an electric motor or at least partially about a shell or a chassis of the object, the ISHE generator configured to generate electric power from an electromagnetic field generated by the electric motor of the object, the ISHE generator comprising:
a positive electrical coupling;
a negative electrical coupling;
a ferromagnet configured to generate a second electromagnetic field to modify the electromagnetic field generated by the electric motor;
a polymer layer disposed on and between each of the positive and negative electrical couplings, wherein the polymer layer separates the positive and negative couplings from each other and separates the ferromagnet from each of the positive and negative couplings, the polymer layer comprising a dielectric, the dielectric increasing resistance of a flow of electricity between the ferromagnet and the positive or negative electrical couplings via the polymer layer; and
a plurality of electrical leads each coupled to corresponding of the positive and negative electrical couplings, each of the plurality of electrical leads disposed about the electric motor of the object, each of the electrical leads configured to interact with the polymer layer and with the electromagnetic field generated by the electric motor and modified by the ferromagnet, wherein in response to an interaction of the plurality of electrical leads with the polymer layer and with the modified electromagnetic field, the positive and negative electrical couplings are configured to generate a flow of electrons along the plurality of electrical leads in response to a spin state of electrons within the polymer layer to at least one of power the plurality of piezoceramic transducers or charge the battery of the object via the flow of electrons.

99. The fluid dynamic system of claim 98, further comprising an antenna configured to be positioned at least partially about the electric motor of the object, the antenna configured to detect an electromagnetic field emitted by the electric motor and to generate a field signal indicative of the electromagnetic field.

100. The fluid dynamic system of claim 99, further comprising an electromagnetic receiver configured to receive the field signal from the antenna and to determine, based on the field signal, resonance electromagnetic waves that resonate with the electromagnetic field emitted by the electric motor, the electromagnetic receiver configured to cause the antenna to emit the resonance electromagnetic waves toward the shell or the chassis of the object, wherein the electromagnetic field emitted by the electric motor is based on a speed of operation of the electric motor.

101. The fluid dynamic system of claim 100, further comprising a plurality of dielectric rods each configured to connect to the shell or the chassis of the object and to the electric motor, each of the plurality of dielectric rods configured to receive the electromagnetic field from the electric motor and to transmit the electromagnetic field to the shell or the chassis of the object.

102-105. (canceled)

106. A fluid dynamic system configured to reduce fluid drag on a moving object, the system comprising:
a plurality of piezoceramic transducers configured to be positioned proximate to an exterior surface of the object, the plurality of piezoceramic transducers each configured convert electric current from a battery of the object to ultrasound waves and to emit the ultrasound waves toward fluid proximate the exterior surface of the object that exerts pressure on the exterior of the object as the object moves through the fluid to convert turbulent flow of the fluid to laminar flow proximate the exterior of the object to reduce pressure exerted by the fluid on the exterior of the object moving through the fluid, thereby reducing fluid drag on the object;
a plurality of pressure sensors configured to be positioned proximate to the exterior surface of the object, the plurality of pressure sensors each configured to detect a pressure of the fluid at a location of a corresponding piezoceramic transducer and to generate a pressure signal corresponding to the pressure at the location;
a controller configured to receive the pressure signal from each of the plurality of pressure sensors and to determine a target ultrasound wave based on the pressure signal for the corresponding piezoceramic transducer to emit the target ultrasound wave to convert turbulent flow of the fluid to laminar flow of the fluid proximate the exterior of the object to reduce fluid drag on the object;
an antenna configured to be positioned at least partially about an electric motor of the object, the antenna configured to detect an electromagnetic field emitted by the electric motor and to generate a field signal indicative of the electromagnetic field;
an electromagnetic receiver configured to receive the field signal from the antenna and to determine, based on the field signal, resonance electromagnetic waves that resonate with the electromagnetic field emitted by the electric motor, the electromagnetic receiver configured to cause the antenna to emit the resonance electromagnetic waves toward a shell or a chassis of the object, wherein the electromagnetic field emitted by the electric motor is based on a speed of operation of the electric motor; and
a plurality of dielectric rods each configured to connect to the shell or the chassis of the object and to the electric motor, each of the plurality of dielectric rods configured to receive the electromagnetic field from the electric motor and to transmit the electromagnetic field to the shell or the chassis of the object,
wherein the electromagnetic field at the shell or the chassis of the object resonates with the resonance electromagnetic waves at the shell or the chassis of the object to power the plurality of piezoceramic transducers via the resonance in the shell or the chassis of the object to reduce power output from the battery for causing emission of the ultrasound waves by the plurality of piezoceramic transducers.

107. (canceled)

108. (canceled)

109. The fluid dynamic system of claim 106, further comprising an inverse spin hall effect (ISHE) generator configured to be positioned at least partially about an electric motor or at least partially about a shell or a chassis of the object, the ISHE generator configured to generate electric power from an electromagnetic field generated by the electric motor of the object, the ISHE generator comprising a positive electrical coupling and a negative electrical coupling.

110. The fluid dynamic system of claim 109, wherein the ISHE generator further comprises a ferromagnet configured to generate a second electromagnetic field to modify the electromagnetic field generated by the electric motor.

111. The fluid dynamic system of claim 110, wherein the ISHE generator further comprises a polymer layer disposed on and between each of the positive and negative electrical couplings, wherein the polymer layer separates the positive and negative couplings from each other and separates the ferromagnet from each of the positive and negative couplings.

112. The fluid dynamic system of claim 111, wherein the polymer layer comprises a dielectric, the dielectric increasing resistance of a flow of electricity between the ferromagnet and the positive or negative electrical couplings via the polymer layer.

113. The fluid dynamic system of claim 111, wherein the ISHE generator further comprises a plurality of electrical leads each coupled to corresponding of the positive and negative electrical couplings, each of the plurality of electrical leads disposed about the electric motor of the object.

114. The fluid dynamic system of claim 113, wherein each of the electrical leads is configured to interact with the polymer layer and with the electromagnetic field generated by the electric motor and modified by the ferromagnet.

115. The fluid dynamic system of claim 114, wherein in response to an interaction of the plurality of electrical leads with the polymer layer and with the modified electromagnetic field, the positive and negative electrical couplings are configured to generate a flow of electrons along the plurality of electrical leads in response to a spin state of electrons within the polymer layer to at least one of power the plurality of piezoceramic transducers or charge the battery of the object via the flow of electrons.

116. (canceled)

117. A fluid dynamic system configured to reduce fluid drag on a moving object, the system comprising:
a plurality of piezoceramic transducers configured to be positioned proximate to an exterior surface of the object, the plurality of piezoceramic transducers each configured convert electric current from a battery or an electromagnetic wave generator of the object to ultrasound waves and to emit the ultrasound waves toward fluid proximate the exterior surface of the object that exerts pressure on the exterior of the object as the object moves through the fluid to convert turbulent flow of the fluid to laminar flow proximate the exterior of the object to reduce pressure exerted by the fluid on the exterior of the object moving through the fluid, thereby reducing fluid drag on the object; and
a controller configured to determine a target ultrasound wave for a corresponding piezoceramic transducer to emit the target ultrasound wave to convert turbulent flow of the fluid to laminar flow of the fluid proximate the exterior of the object to reduce fluid drag on the object.

118. The fluid dynamic system of claim 117, further comprising a plurality of pressure sensors configured to be positioned proximate to the exterior surface of the object, the plurality of pressure sensors each configured to detect a pressure of the fluid at a location of a corresponding piezoceramic transducer and to generate a pressure signal corresponding to the pressure at the location, wherein the controller is further configured to receive the pressure signal from each of the plurality of pressure sensors and to determine the target ultrasound waves based on the pressure signal.

119-150. (canceled)

151. The fluid dynamic system of claim 91, further comprising a microwave generator connected to each of the piezoceramic transducers and configured to emit microwaves.

152. The fluid dynamic system of claim 151, wherein the plurality of piezoceramic transducers are each configured to receive the microwaves and convert the microwaves to ultrasound waves and emit the ultrasound waves toward the fluid.

153. The fluid dynamic system of claim 91, wherein the positive and negative electrical couplings are configured to generate the flow of electrons along the plurality of electrical leads further in response to a spin state of electrons within the polymer layer.

154. The fluid dynamic system of claim 91, wherein the plurality of piezoceramic transducers comprises an upper plurality of piezoceramic transducers and a lower plurality of piezoceramic transducers, each of the upper plurality of piezoceramic transducers configured to be positioned proximate to an upper surface of the object with lower pressure from fluid with the object moving through ambient air and each of the lower plurality of piezoceramic transducers configured to be positioned proximate to a lower surface of the object with higher pressure relative to the lower pressure from fluid with the object moving through ambient air.

155. The fluid dynamic system of claim 154, wherein the controller is configured to receive first pressure signals from each of an upper plurality of pressure sensors and to receive second pressure signals from each of a lower plurality of pressure sensors, wherein the controller is configured to determine first target ultrasound waves based on the first pressure signals for piezoceramic transducers corresponding to each of the upper plurality of piezoceramic transducers, wherein the controller is configured to determine second target ultrasound waves based on the second pressure signals for the piezoceramic transducers corresponding to each of the lower plurality of piezoceramic transducers, wherein the target ultrasound waves comprise the first and second target ultrasound waves, the controller configured to cause the plurality of piezoceramic transducers to emit the first and second target ultrasound waves, wherein the first target ultrasound waves have at least one of a higher amplitude or frequency than the second target ultrasound waves.

156. The fluid dynamic system of claim 98, further comprising an inverse hall effect (IHE) generator configured to be positioned at least partially about the electric motor or at least partially about the shell or the chassis of the object and to generate electric power from the electromagnetic field generated by the electric motor of the object, the IHE generator comprising:
an IHE battery comprising a positive and a negative terminal; and
a second plurality of electrical leads each coupled to corresponding terminals of the IHE battery, each of the second plurality of electrical leads disposed about the electric motor of the object, each of the second plurality of electrical leads configured to interact with the electromagnetic field generated by the electric motor, wherein in response to an interaction of the second plurality of electrical leads with the electromagnetic field, the second plurality of electrical leads are configured to at least one of power the plurality of piezoceramic transducers or generate a voltage between the positive and negative terminals of the IHE battery.

157. The fluid dynamic system of claim 156, wherein the IHE generator is configured to generate alternating current.
